(19) United States
(12) Patent Application Publication
(10) Pub. No.: US 2026/0206340 A1
(43) Pub. Date: Jul. 16, 2026

(54) IMAGE SENSOR INCLUDING JUNCTIONLESS TRANSISTORS

(71) Applicant: Samsung Electronics Co., Ltd., Suwon-si (KR)

(72) Inventors: Incheol Cho, Suwon-si (KR); HO-CHUL JI, Suwon-si (KR); Yeonsoo Ahn, Suwon-si (KR)

(21) Appl. No.: 19/439,111

(22) Filed: Jan. 2, 2026

(30) Foreign Application Priority Data
Jan. 10, 2025 (KR) 10-2025-0004378

(51) Int. Cl. H10F 39/00

(52) U.S. Cl. CPC H10F 39/80373; H10F 39/014

(57) ABSTRACT

An image sensor according to an embodiment of the present disclosure may include a deep PD isolation pattern provided in a substrate doped with dopants having a first conductivity type, a shallow element isolation pattern, an active region including a terminal portion and a fin portion, a gate filling a gate recess formed in the shallow element isolation pattern to expose a portion of the fin portion, and a gate insulating layer, wherein the fin portion may include a channel region doped with dopants having a second conductivity type, the terminal portion may include a side region doped with dopants having the second conductivity type, and the side region may vertically overlap the gate.

### CROSS-REFERENCE TO RELATED APPLICATION(S)

This U.S. non-provisional application claims priority under 35 USC § 119 to Korean Patent Application No. 10-2025-0004378, filed on Jan. 10, 2025, in the Korean Intellectual Property Office, the disclosure of which is herein incorporated by reference in its entirety.

### BACKGROUND

The present disclosure relates to an image sensor and a method of manufacturing the same.

An image sensor is a semiconductor element that converts an optical image into an electrical signal. Recently, with the development of the computer industry and the communication industry, the demand for image sensors with improved performance has increased in various fields such as digital cameras, camcorders, personal communication systems (PCSs), gaming devices, security cameras, and medical micro cameras. The image sensors can be classified into a charge coupled device (CCD) type and a complementary metal oxide semiconductor (CMOS) type. The CMOS type image sensor is provided with a plurality of pixels arranged two-dimensionally. Each of the pixels includes a photodiode (PD). The photodiode serves to convert incident light into an electrical signal.

### SUMMARY

The present disclosure may be directed to providing an image sensor with improved electrical characteristics of a transistor and a method of manufacturing the same.

The present disclosure may also be directed to providing an image sensor with improved trans-conductance of a transistor and a method of manufacturing the same.

The present disclosure may also be directed to providing an image sensor with reduced parasitic resistance of a transistor and a method of manufacturing the same.

The present disclosure may also be directed to providing an image sensor with reduced parasitic capacitance of a transistor and a method of manufacturing the same.

The present disclosure may also be directed to providing an image sensor including a junctionless transistor having a channel region substantially uniformly doped and a method of manufacturing the same.

The present disclosure may also be directed to providing an image sensor with a transistor having an increased channel region and a method of manufacturing the same.

The present disclosure may also be directed to providing an image sensor with a bulk channel region formed inside a fin and a method of manufacturing the same.

The present disclosure may also be directed to providing an image sensor with a channel region formed by an isotropic doping process and a method of manufacturing the same.

The present disclosure may also be directed to providing a method of manufacturing an image sensor in which a manufacturing process is simplified and a manufacturing cost is reduced.

An image sensor according to one embodiment of the present disclosure may include a deep PD isolation pattern provided in a substrate doped with dopants having a first conductivity type to define photodiode region groups, each of the photodiode region groups including at least one photodiode region, a shallow element isolation pattern filling a shallow trench recessed from a first surface of the substrate to define at least one active region in each of the photodiode region groups, the active region including a terminal portion and a fin portion, a gate filling a gate recess formed in the shallow element isolation pattern to expose a portion of the fin portion, and a gate insulating layer between the gate and the exposed portion of the fin portion, wherein the fin portion may include a channel region formed in the exposed portion of the fin portion and doped with dopants having a second conductivity type different from the first conductivity type, the terminal portion may include a side region defining the gate recess and doped with dopants having the second conductivity type, and the side region may vertically overlap the gate.

The channel region may be uniformly doped with dopants having the second conductivity type in the vertical direction.

The side region may be uniformly doped with dopants having the second conductivity type.

A dopant concentration of the side region may be the same as a dopant concentration of the channel region.

The side region may extend in a direction intersecting a longitudinal direction of the channel region.

The terminal portion may further include a source/drain region connected to the side region and doped with dopants having the second conductivity type, and the source/drain region may not vertically overlap the gate.

A dopant concentration of the source/drain region may be greater than a dopant concentration of the side region.

The side region may be positioned between the source/drain region and the channel region, and the side region may connect the source/drain region and the channel region.

The side region may include an upper portion connected to the source/drain region, and a lower portion positioned under the upper portion, and a dopant concentration of the upper portion may be greater than a dopant concentration of the lower portion.

The gate may be doped with dopants having the first conductivity type.

An image sensor according to one embodiment of the present disclosure may include a deep PD isolation pattern provided in a substrate doped with dopants having a first conductivity type to define photodiode region groups, each of the photodiode region groups including at least one photodiode region, a shallow element isolation pattern filling a shallow trench recessed from a first surface of the substrate to define at least one active region in each of the photodiode region groups, the active region including a terminal portion and a fin portion, a gate filling a gate recess formed in the shallow element isolation pattern to expose a portion of the fin portion, the gate including a plurality of vertical portions spaced apart from each other in the gate recess, and a gate insulating layer between the gate and the exposed portion of the fin portion, wherein the fin portion may include a channel region formed in the exposed portion of the fin portion and doped with dopants having a second conductivity type different from the first conductivity type, the terminal portion may include a source/drain region doped with dopants having the second conductivity type, and a side region provided between the fin portion and the source/drain region and doped with dopants having the second conductivity type, and a dopant concentration of the side region may be less than a dopant concentration of the source/drain region.

A level of an upper end of the fin portion may be the same as a level of the first surface of the substrate, and the fin portion may disconnect the vertical portions from each other.

A level of an upper surface of the fin portion may be lower than a level of the first surface of the substrate, the gate may include a horizontal portion connected to the vertical portions, and a level of an upper surface of the horizontal portion may be the same as a level of the first surface of the substrate.

A width of the fin portion defined in a width direction of the channel region may increase toward the first surface of the substrate.

A method of manufacturing an image sensor according to one embodiment of the present disclosure may include patterning a first surface of a substrate to form a shallow trench defining an active region, the active region including a terminal portion and a fin portion, forming a shallow element isolation pattern filling the shallow trench, patterning the shallow element isolation pattern to form a gate recess exposing side surfaces of the fin portion, performing an isotropic doping process to form a channel region in the fin portion through an upper surface and the side surfaces of the fin portion, forming a gate insulating layer on the fin portion, and forming a gate filling the gate recess.

The performing of the isotropic doping process may include conformally forming a doping film including dopants on the upper surface and the exposed side surfaces of the fin portion, and performing an annealing process to diffuse the dopants of the doping film into the fin portion.

The performing of the isotropic doping may include uniformly doping dopants in a plasma on the upper surface and the exposed side surfaces of the fin portion.

The method of manufacturing an image sensor may further include forming a source/drain region in the terminal portion, wherein the source/drain region may be doped with dopants having the same conductivity type as that of the channel region.

The source/drain region may be simultaneously formed with the channel region by the performing of the isotropic doping process.

The terminal portion may include a sidewall portion defining the gate recess and connected to the fin portion, a side region may be formed in the sidewall portion by the performing of the isotropic doping process, and the side region may be doped with dopants having the same conductivity type as that of the channel region.

### BRIEF DESCRIPTION OF DRAWINGS

FIG. 1 is a block diagram of an image sensor according to some embodiments of the present disclosure.

FIG. 2 is a circuit diagram of pixels included in a pixel array of an image sensor according to some embodiments of the present disclosure.

FIG. 3 is a circuit diagram of pixels included in a pixel array of an image sensor according to one embodiment of the present disclosure.

FIG. 4 is a plan view of an image sensor according to one embodiment of the present disclosure.

FIG. 5 is an enlarged plan view of one photodiode region group of FIG. 4.

FIG. 6A is a cross-sectional view taken along line I-I′ of FIG. 5.

FIG. 6B is a cross-sectional view taken along line II-II′ of FIG. 5.

FIG. 6C is a cross-sectional view taken along line III-III′ of FIG. 5.

FIGS. 7A to 13A are cross-sectional views for showing a method of manufacturing an image sensor according to one embodiment of the present disclosure, which are cross-sectional views corresponding to line I-I′ of FIG. 5.

FIGS. 7B-13B, FIG. 14A, and 15A show the method of manufacturing the image sensor according to one embodiment of the present disclosure, which are cross-sectional views corresponding to line II-II′ of FIG. 5.

FIGS. 7C-13C, FIG. 14B, and 15B show the method of manufacturing the image sensor according to one embodiment of the present disclosure, which are cross-sectional views corresponding to line III-III′ of FIG. 5.

FIG. 16A is a cross-sectional view of an image sensor according to one embodiment of the present disclosure, which is a cross-sectional view corresponding to line I-I′ of FIG. 5.

FIG. 16B is a cross-sectional view of the image sensor according to one embodiment of the present disclosure, which is a cross-sectional view corresponding to line II-II′ of FIG. 5.

FIG. 16C is a cross-sectional view of the image sensor according to one embodiment of the present disclosure, which is a cross-sectional view corresponding to line III-III′ of FIG. 5.

FIGS. 17A to 19A are cross-sectional views for showing a method of manufacturing an image sensor according to one embodiment of the present disclosure.

FIGS. 17B to 19B are cross-sectional views for showing the method of manufacturing the image sensor according to one embodiment of the present disclosure.

FIG. 20A is a cross-sectional view of an image sensor according to one embodiment of the present disclosure, which is a cross-sectional view corresponding to line I-I′ of FIG. 5.

FIG. 20B is a cross-sectional view of the image sensor according to one embodiment of the present disclosure, which is a cross-sectional view corresponding to line II-II′ of FIG. 5.

FIG. 20C is a cross-sectional view of the image sensor according to one embodiment of the present disclosure, which is a cross-sectional view corresponding to line III-III′ of FIG. 5.

FIG. 21A is a cross-sectional view of an image sensor according to one embodiment of the present disclosure, which is a cross-sectional view corresponding to line II-II′ of FIG. 5.

FIG. 21B is a cross-sectional view of the image sensor according to one embodiment of the present disclosure, which is a cross-sectional view corresponding to line III-III′ of FIG. 5.

FIG. 22 is a cross-sectional view of an image sensor according to one embodiment of the present disclosure, which is a cross-sectional view corresponding to line I-I′ of FIG. 5.

FIG. 23 is an enlarged plan view of one photodiode region group of an image sensor according to one embodiment of the present disclosure.

### DETAILED DESCRIPTION

Hereafter, the embodiments of the present disclosure will be clearly and thoroughly described with reference to the accompanying drawings.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

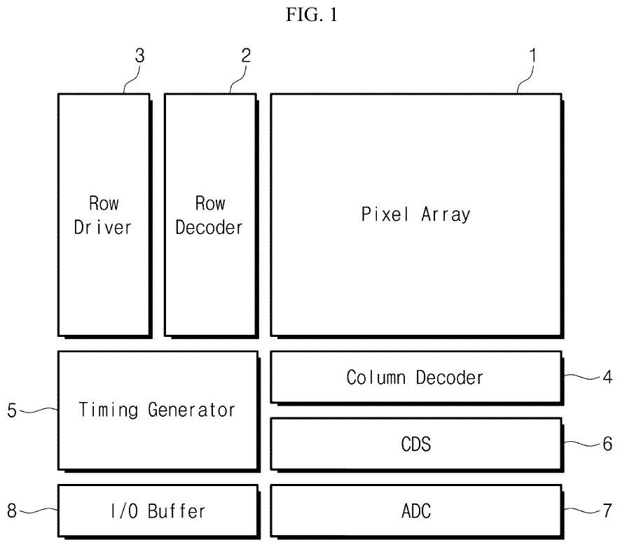

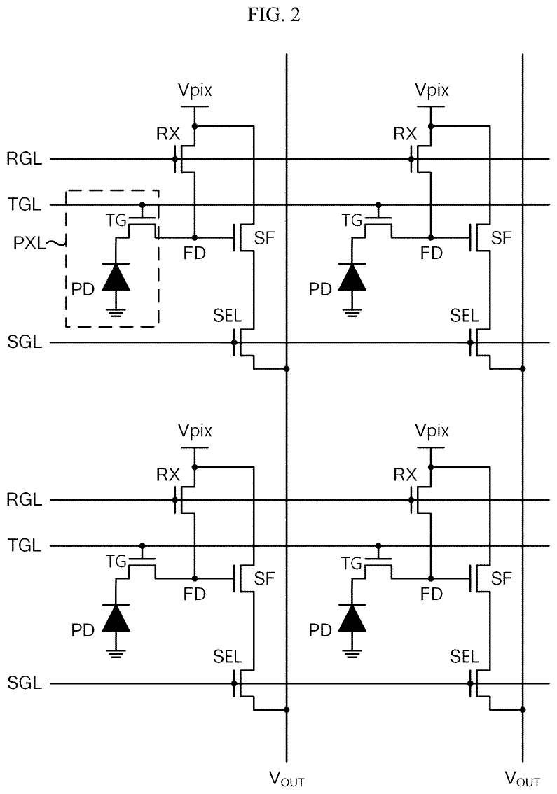

FIG. 1 is a block diagram of an image sensor according to some embodiments of the present disclosure.

Referring to FIG. 1, the image sensor according to some embodiments of the present invention may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

The pixel array 1 may include a plurality of pixels arranged two-dimensionally, and the pixels may convert optical signals into electrical signals. The pixel array 1 may be driven by a plurality of driving signals (e.g., a pixel selection signal, a reset signal, and/or a charge transfer signal) transmitted from the row driver 3. The converted electrical signals may be provided to the CDS 6.

The row driver 3 may provide the plurality of driving signals for driving the plurality of pixels based on decoded results from the row decoder 2 to the pixel array 1. When the pixels are arranged in a matrix form, the driving signals may be provided in a row unit.

The timing generator 5 may provide a timing signal and a control signal to the row decoder 2 and the column decoder 4.

The CDS 6 may receive the electrical signals generated from the pixel array 1 and may hold and sample the received signals. The CDS 6 may double-sample a specific noise level and a signal level caused by an electrical signal to output a difference level corresponding to the difference between the noise level and the signal level.

The ADC 7 may convert an analog signal corresponding to the difference level output from the CDS 6 into a digital signal and may output the digital signal.

The I/O buffer 8 may latch the digital signals and sequentially output the latched signals to an image signal processor (not shown) based on the decoded results from the column decoder 4.

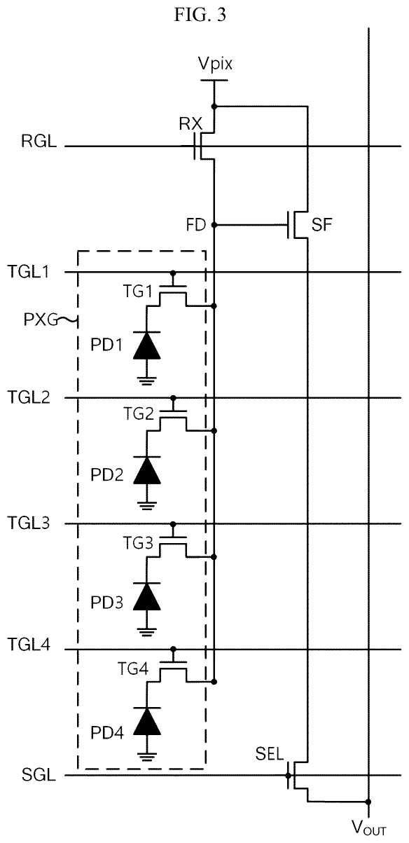

FIG. 2 is a circuit diagram of pixels included in a pixel array of an image sensor according to some embodiments of the present disclosure.

Referring to FIG. 2, the pixel array may include pixels PXL, and the pixels PXL may be arranged in a matrix form. Each of the pixels PXL may include pixel transistors and a transfer transistor gate TG. And each of the pixels PXL may be connected to corresponding logic transistors or a plurality of pixels PXL may share logic transistors and a floating diffusion region FD. The logic transistors may include a reset transistor RX, a selection transistor SEL, and a source follower transistor SF.

The photodiode PD may generate and accumulate photocharges in proportion to an amount of light incident from the outside. The photodiode PD may include a photodiode, a phototransistor, a photogate, a pinned photodiode, or a combination thereof. The transfer transistor gate TG may transfer the photocharges generated from the photodiode PD to the floating diffusion region FD. A transfer transistor gate TG may be connected to a transfer gate line TGL. The floating diffusion region FD may receive and cumulatively store the photocharges generated from the photodiode PD.

A gate of the source follower transistor SF may be connected to the floating diffusion region FD. A drain terminal of the source follower transistor SF may be connected to a power supply voltage Vₚᵢₓ that may receive a power voltage. The source follower transistor SF may be controlled according to an amount of the photocharges accumulated in the floating diffusion region FD. The source follower transistor SF may convert a signal corresponding to an amount of input photocharges into a voltage signal.

The reset transistor RX may periodically reset the charges accumulated in the floating diffusion region FD. A gate of the reset transistor RX may be connected to a reset gate line RGL. A source terminal of the reset transistor RX may be connected to the floating diffusion region FD, and a drain terminal of the reset transistor RX may be connected to the power supply voltage Vₚᵢₓ. When the reset transistor RX is turned on, the power voltage of the power supply voltage Vₚᵢₓ may be applied to the floating diffusion region FD through the reset transistor RX. For example, when the reset transistor RX is turned on, the charges accumulated in the floating diffusion region FD may be discharged by the power voltage, thereby resetting the floating diffusion region FD.

The source follower transistor SF may serve as a source follower buffer amplifier. The source follower transistor SF may amplify a potential change in floating diffusion region FD and output the amplified potential change to an output line V_{OUT}.

A gate of the selection transistor SG may be connected to a selection gate line SGL. A drain terminal of the selection transistor SG may be connected to a source terminal of the source follower transistor DX, and a source terminal of the selection transistor SG may be connected to the output line V_{OUT}. The selection transistors SG of the pixels PXL to be readout in a row unit may be selected by a selection signal applied through the corresponding selection gate line SGL. When the selection transistor SG is turned on, the potential change amplified by the source follower transistor SF may be output to the output line V_{OUT} through the selection transistor SG.

FIG. 3 is a circuit diagram of pixels included in a pixel array of an image sensor according to one embodiment of the present disclosure.

Referring to FIG. 3, the pixel array may include a plurality of pixel groups PXG, and each of the pixel groups PXG may include a plurality of pixels. A circuit diagram of one pixel group PXG is shown in FIG. 3.

Referring to FIG. 3, in one embodiment, the pixel group PXG may include four pixels (that is, first to fourth pixels). The first to fourth pixels may respectively include first to fourth transfer transistor gates TG1, TG2, TG3, and TG4 and first to fourth photodiodes PD1, PD2, PD3, and PD4. Each of the first to fourth transfer transistor gates TG1, TG2, TG3, and TG4 may be respectively connected to first to fourth transfer gate lines TGL1, TGL2, TGL3, and TGL4. The first to fourth pixels may share the reset transistor RX, the source follower transistor SF, and the selection transistor SEL that are previously disclosed.

In the embodiments of FIG. 3, the pixel group PXG includes four pixels, but the embodiments of the present disclosure are not limited thereto. The number of pixels in the pixel group PXG may be variously changed. For example, the number of pixels in the pixel group PXG may be eight.

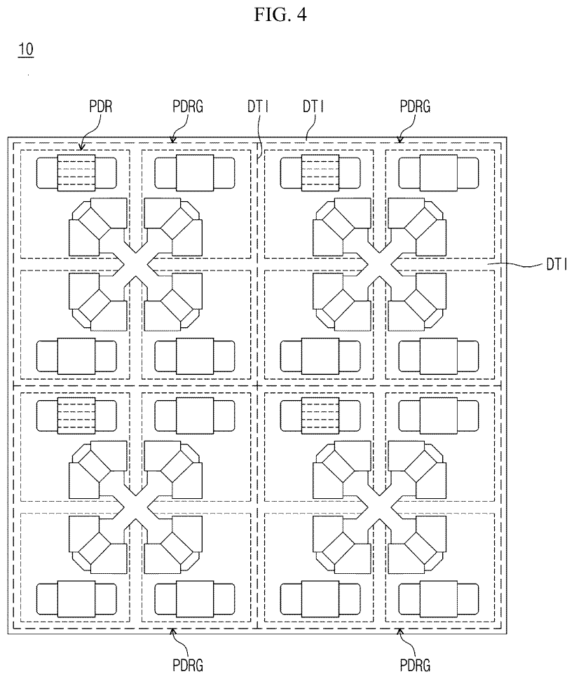

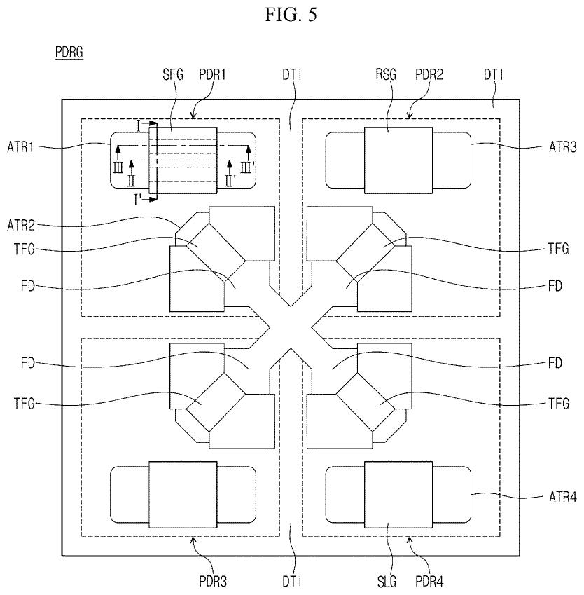

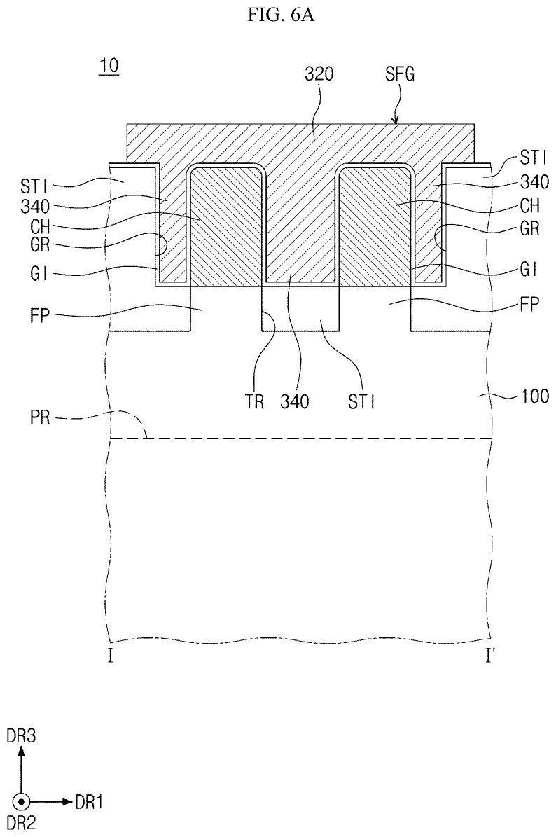

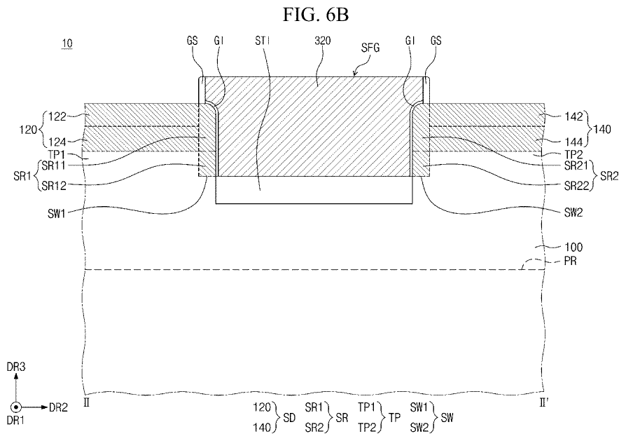

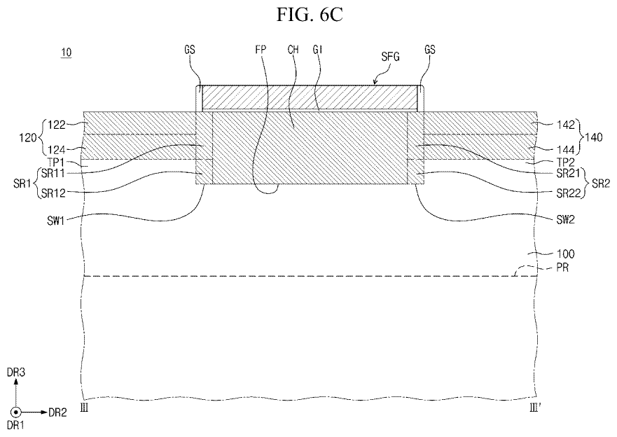

FIG. 4 is a plan view of an image sensor 10 according to one embodiment of the present disclosure. FIG. 5 is an enlarged plan view of one photodiode region group of FIG. 4. FIG. 6A is a cross-sectional view taken along line I-I′ of FIG. 5. FIG. 6B is a cross-sectional view taken along line II-II′ of FIG. 5. FIG. 6C is a cross-sectional view taken along line III-III′ of FIG. 5.

Referring to FIGS. 4 to 6C, a deep PD isolation pattern DTI may be provided in a substrate 100 to define a plurality of photodiode region groups PDRG, each of which includes a plurality of photodiode regions PDR. Furthermore, the deep PD isolation pattern DTI may extend into each of the photodiode region groups PDRG to define the photodiode regions PDR. For example, the deep PD isolation pattern DTI may also be provided between the photodiode regions PDR.

The substrate 100 may have a first surface and a second surface opposite to the first surface. The first surface of the substrate 100 may be a front surface of the substrate 100, and the second surface of the substrate 100 may be a back surface of the substrate 100.

In one embodiment, a deep PD isolation pattern DTI may pass through the substrate 100. For example, the deep PD isolation pattern DTI may fill a deep trench that passes through the substrate 100. The deep PD isolation pattern DTI may be provided in a substantially grid shape in a plan view. Each of the photodiode regions PDR may be a portion of the substrate 100 surrounded by the deep PD isolation pattern DTI.

A shallow element isolation pattern STI may be provided in the substrate 100 to define a plurality of active regions in each of the photodiode region groups PDRG. The shallow element isolation pattern STI may fill a shallow trench TR recessed from the first surface of the substrate 100. For example, the shallow element isolation pattern STI may be provided in the substrate 100 and may be adjacent to the first surface of the substrate 100. Each of the active regions may be a portion of the substrate 100 (that is, a portion of the photodiode region PDR) surrounded by the shallow element isolation pattern STI in a plan view.

The plurality of active regions may include a first active region ATR1, a second active region ATR2, a third active region ATR3, and a fourth active region ATR4. A source follower transistor SF may be provided in the first active region ATR1, and a transfer transistor TG may be provided in the second active region ATR2. A reset transistor RG may be provided in the third active region ATR3, and a selection transistor SG may be provided in the fourth active region ATR4. For example, a source follower gate SFG may be disposed on the first active region ATR1, and a transfer gate TFG may be disposed on the second active region ATR2. A reset gate RSG may be disposed on the third active region ATR3, and a selection gate SLG may be disposed on the fourth active region ATR4.

In some embodiments, the first active region ATR1 may be positioned in any one of the photodiode regions PDR of each of the photodiode region groups PDRG. Referring to FIG. 5, in one embodiment, each of the photodiode region groups PDRG may include first to fourth photodiode regions PDR1, PDR2, PDR3, and PDR4, and the first active region ATR1 may be defined in the first photodiode region PDR1.

In some embodiments, the second active region ATR2 may be defined in each of the photodiode regions PDR of each of the photodiode region groups PDRG. For example, as shown in FIG. 5, the second active region ATR2 may be defined in each of the first to fourth photodiode regions PDR1 to PDR4. In this case, the transfer gate TFG may be disposed on each of the second active regions ATR2. In one embodiment, the second active regions ATR2 of each of the photodiode region groups PDRG may extend and be connected to each other.

The third active region ATR3 may be defined in another one of the photodiode regions PDR of each of the photodiode region groups PDRG, and the fourth active region ATR4 may be defined in still another one of the photodiode regions PDR of each of the photodiode region groups PDRG. For example, as shown in FIG. 5, the third active region ATR3 may be defined in the second photodiode region PDR2, and the fourth active region ATR4 may be defined in the fourth photodiode region PDR4. In one embodiment, an additional transistor may be provided in another active region defined in the third photodiode region PDR3. The additional transistor may be a dummy transistor or a transistor (e.g., a dual conversion gain transistor) performing an additional function.

A floating diffusion region FD may be provided in the second active region ATR2 at one side of the transfer gate TFG. The floating diffusion regions FD of each of the photodiode regions PDR (e.g., PDR1-PDR4) may extend along the second active regions ATR2 and be connected to each other.

A photodiode PD may be provided in each of the photodiode regions PDR. A first region of the substrate 100 (i.e., a first region of each of the photodiode regions PDR) may be doped with impurities having a first conductivity type, and a second region of the substrate 100 (i.e., a second region of each of the photodiode regions PDR) may be doped with impurities having a second conductivity type different from the first conductivity type. One of the first conductivity type and the second conductivity type may be a P-type, and the other of the first conductivity type and the second conductivity type may be a N-type. For example, the first conductivity type may be the P-type, and the second conductivity type may be the N-type. Accordingly, the first region of the substrate 100 and the second region of the substrate 100 may be P-N junctioned to form a photodiode. The floating diffusion region FD may be doped with impurities having the second conductivity type. In semiconductor technology, if a semiconductor contains both p-type and n-type impurities, the conductivity-type of the semiconductor will be determined by which type of impurity is in greater concentration. Therefore, if a semiconductor has both p-type and n-type impurities, the net conductivity type will be determined by the dominant impurity concentration. As used herein, a semiconductor region of a “first conductivity-type” denotes that the dominant impurities in the semiconductor region is (or are) a first conductivity-type impurity. As used herein, a “oncentration of the first conductivity-type” in the semiconductor region (or a “doping concentration”) refers to the net concentration of the impurities in the semiconductor region (i.e., (the amount of first conductivity-type impurities minus the amount of second conductivity-type impurities)/the volume of the semiconductor region).

The first active region ATR1 may include a terminal portion TP and a fin portion FP. The fin portion FP may pass through the shallow element isolation pattern STI. Therefore, a portion of the fin portion FP may protrude from the shallow element isolation pattern STI.

A gate recess GR may be formed in the shallow element isolation pattern STI. The gate recess GR may be formed by recessing one surface of the shallow element isolation pattern STI. The gate recess GR may be defined by the fin portion FP, the terminal portion TP, and the shallow element isolation pattern STI. A portion of the fin portion FP may be exposed by the gate recess Gr. The portion of the fin portion FP exposed by the gate recess Gr may correspond to an upper portion of the fin portion FP (e.g., exposed portion of the fin portion FP).

The fin portion FP may include a channel region CH doped with dopants. The channel region CH may be formed in the portion of the fin portion FP exposed by the gate recess GR (i.e., the upper (exposed) portion of the fin portion FP). For example, the channel region CH may be formed in the portion of the fin portion FP protruding from the shallow element isolation pattern STI.

The channel region CH may be doped with dopants having the second conductivity type different from the first conductivity type. For example, the channel region CH may be substantially uniformly doped with dopants having the second conductivity type. For example, the channel region CH may be substantially uniformly doped with dopants having the second conductivity type in a depth direction of the channel region CH. The depth direction of the channel region CH may correspond to a third direction DR3. The third direction DR3 may be referred to as an up-down or vertical direction.

The remaining portion of the fin portion FP may correspond to a lower portion (e.g., non-exposed portion). The remaining portion of the fin portion FP may be positioned in the shallow element isolation pattern STI. The remaining portion of the fin portion FP may not be substantially doped with dopants. The remaining portion of the fin portion FP may be connected to the substrate 100. The remaining portion of the fin portion FP may connect the substrate 100 and the upper (exposed) portion of the fin portion FP.

The terminal portion TP may include a source/drain region SD doped with dopants having the second conductivity type. A conductivity type of the source/drain region SD may be the same as a conductivity type of the channel region CH. Therefore, a junctionless transistor may be provided. A junctionless transistor may include the channel region CH and the source/drain region SD doped with the same conductivity type as described above. The junctionless transistor may further include a gate electrode configured to control the flow of current between source and drain.

The terminal portion TP may include a first terminal portion TP1 provided at one side of the fin portion FP and a second terminal portion TP2 provided at the other side of the fin portion FP. The source/drain region SD may include a first source/drain region 120 on the first terminal portion TP1 and a second source/drain region 140 on the second terminal portion TP2. The first source/drain region 120 may be provided on a portion of the first terminal portion TP1. The second source/drain region 140 may be provided on a portion of the second terminal portion TP2.

The source/drain region SD may not vertically overlap the source follower gate SFG. For example, the source/drain region SD may be positioned outside the source follower gate SFG in a plan view.

The first source/drain region 120 may include an upper region 122 and a lower region 124. The upper region 122 may be adjacent to a first surface of the substrate 100, and the lower region 124 may be provided under the upper region 122. Similarly, the second source/drain region 140 may include an upper region 142 and a lower region 144. The upper region 142 may be adjacent to the first surface of the substrate 100, and the lower region 144 may be provided under the upper region 142.

The terminal portion TP may include a sidewall portion SW connected to the fin portion FP. For example, the first terminal portion TP1 may include a first sidewall portion SW1 connected to the fin portion FP, and the second terminal portion TP2 may include a second sidewall portion SW2 connected to the fin portion FP.

The terminal portion TP may further include a side region SR provided in the sidewall portion SW. The side region SR may be provided between the source/drain region SD and the channel region CH. For example, the side region SR may include a first side region SR1 provided in the first sidewall portion SW1 and a second side region SR2 provided in the second sidewall portion SW2.

The side region SR may be doped with dopants having the second conductivity type. The side region SR may connect the source/drain region SD and the channel region CH.

A dopant concentration of the side region SR may be substantially the same as a dopant concentration of the channel region CH. For example, the dopant concentration of the side region SR and the dopant concentration of channel region CH, at a boundary region in which the side region SR and the channel region CH are in contact with each other, may be substantially the same. Accordingly, the dopant concentration does not vary (i.e., it is the same) across the boundary region between the side region SR and the channel region CH. The dopant concentration of the side region SR may be less than a dopant concentration of the source/drain region SD. For example, the dopant concentration of the source/drain region SD may be greater than that of the side region SR.

In some embodiments, the side region SR may include upper portions SR11 and SR21 that are connected to the source/drain region SD. The side region SR may further include lower portions SR12 and SR22 that are positioned under the upper portions SR11 and SR21 in the third direction DR3. The upper portions SR11 and SR21 of the side region SR may be respectively directly connected to the upper region 122 and the upper region 142 of the source/drain region SD. The upper portions SR11 and SR21 of the side region SR may also be respectively directly connected to the and the lower region 124 and the lower region 144 of the source/drain region SD. Dopant concentrations of the upper portions SR11 and SR21 of the side region SR may be greater than dopant concentrations of the lower portions SR12 and SR22 of the side region SR. In contrast to the foregoing, in some embodiments, the lower portions SR12 and SR22 of the side region SR may be omitted. In this case, the side region SR may be substantially uniformly doped with dopants having the second conductivity type. For example, the side region SR may be substantially uniformly doped with dopants in a depth direction.

The side region SR may vertically overlap the source follower gate SFG. For example, in the third direction DR3, the side region SR may be provided under a horizontal portion 320 of the source follower gate SFG. In addition, in the third direction DR3, the side region SR may also be provided under a gate spacer GS formed on a side surface of the horizontal portion 320 of the source follower gate SFG.

The side regions SR1 and SR2 may be spaced apart from each other in a longitudinal direction of the channel region CH. The side regions SR1 and SR2 may be provided at one side and the other side of the fin portion FP, respectively. The side regions SR1 and SR2 may extend in a direction intersecting the longitudinal direction of the channel region Ch. For example, the longitudinal direction of the channel region CH may be defined as a second direction DR2, and the side regions SR1 and SR2 may extend in a first direction DR1 orthogonal to the second direction DR2. The first direction DR1 and the second direction DR2 may be referred to as horizontal directions (e.g., a first horizontal direction and a second horizontal direction, respectively). The third direction DR3 is orthogonal to the first direction DR1 and the second direction DR2.

The source follower gate SFG may fill the gate recess GR. The source follower gate SFG may include vertical portions 340 filling the gate recess GR and the horizontal portion 320 connected to the vertical portions 340.

The vertical portions 340 may be disposed between the fin portion FP and the shallow element isolation pattern STI. In one embodiment, the vertical portions 340 may also be disposed between the fin portions FP.

The vertical portions 340 may be disposed between the side regions SR1 and SR2. The shallow element isolation pattern STI may be positioned below the vertical portions 340.

The horizontal portion 320 may be provided over the fin portion FP. The horizontal portion 320 may cover a portion of the shallow element isolation pattern STI. The horizontal portion 320 may be provided over the side region SR. The horizontal portion 320 may vertically overlap the side region SR, but may not vertically overlap the source/drain region SD.

The source follower gate SFG may include a polysilicon gate doped with dopants having the first conductivity type, or a metal gate having a work function substantially identical to that of the polysilicon gate.

A gate insulating layer GI may be interposed between the source follower gate SFG and the fin portion FP. The gate insulating layer GI may conformally cover an inner surface of the gate recess GR. The gate insulating layer GI may also be provided between the source follower gate SFG and the shallow element isolation pattern STI. The gate insulating layer GI may also be provided between the source follower gate SFG and the terminal portion TP. For example, the gate insulating layer GI may also be provided between the source follower gate SFG and the sidewall portion SW in which the side region SR is provided.

The gate spacer GS may be provided on the side surface of the horizontal portion 320 of the source follower gate SFG. The gate spacer GS may be provided over the side region SR. An edge of the gate spacer GS may be vertically aligned (e.g., coplanar) with an edge of the source/drain region SD. In addition, the edge of the gate spacer GS may be vertically aligned with an edge of the side region SR.

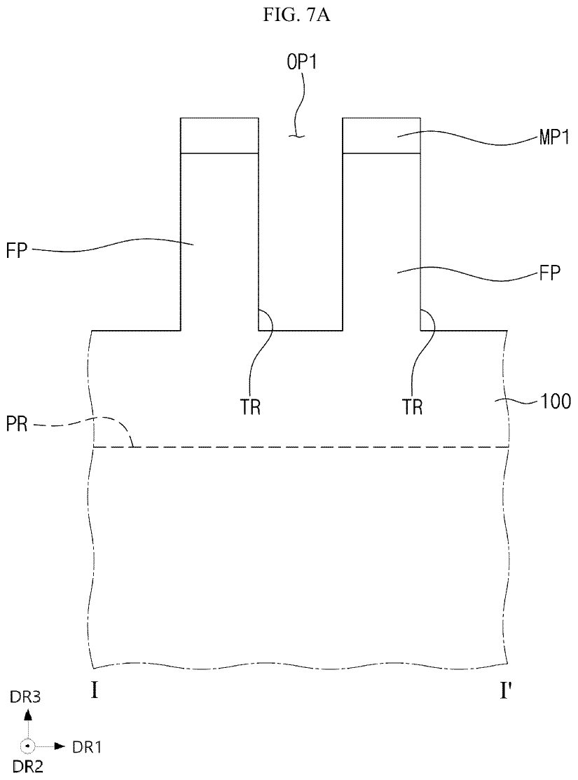

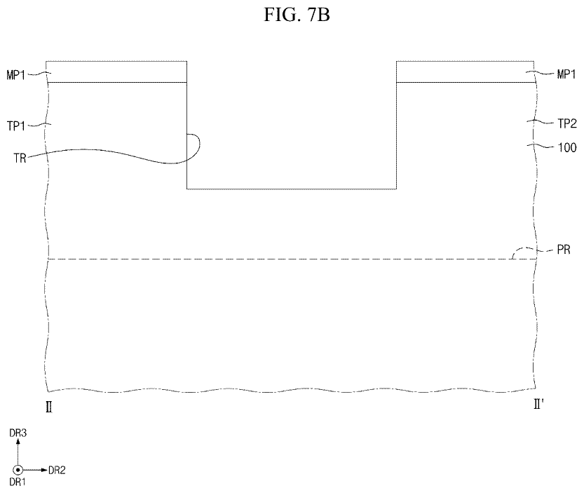

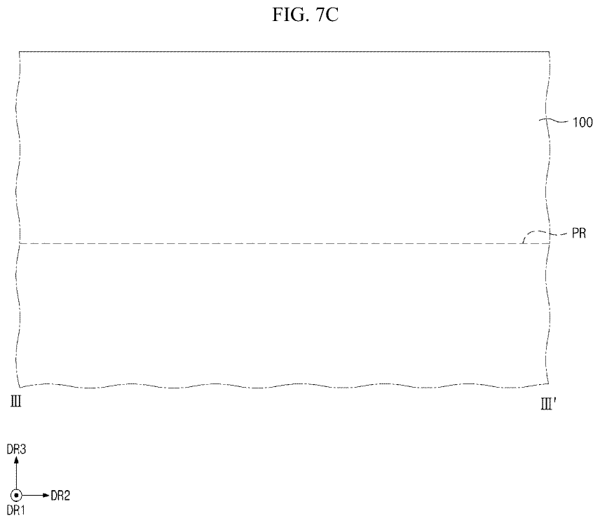

FIGS. 7A to 13A are cross-sectional views for showing a method of manufacturing an image sensor 10 according to one embodiment of the present disclosure, which are cross-sectional views corresponding to line I-I′ of FIG. 5. FIGS. 7B-13B, FIG. 14A, and 15A show the method of manufacturing the image sensor 10 according to one embodiment of the present disclosure, which are cross-sectional views corresponding to line II-II′ of FIG. 5. FIGS. 7C-13C, FIG. 14B, and 15B show the method of manufacturing the image sensor 10 according to one embodiment of the present disclosure, which are cross-sectional views corresponding to line III-III′ of FIG. 5.

Referring to FIGS. 7A to 7C, a substrate 100 may be prepared. The substrate 100 may be a semiconductor substrate including silicon (Si), germanium (Ge), silicon-germanium (Si-Ge), or the like, or may be a compound semiconductor substrate. For example, the substrate 100 may be a silicon substrate.

A shallow trench TR may be formed by patterning the first surface of the substrate 100 to define a first active region ATR1. For example, a first mask pattern MP1 covering the first active region ATR1 may be formed on the first surface of the substrate 100. The first mask pattern MP1 may have a first opening OP1 defining the shallow trench TR. An etching process may be performed on the first surface of the substrate 100 using the first mask pattern MP1 as an etch mask. The etching process may include a front-side anisotropic etching process. Accordingly, the first active region ATR1 may be formed.

The first active region ATR1 may include a terminal portion TP and a fin portion FP. A plurality of the fin portions FP may be formed. The terminal portions TP may be formed as a pair. The fin portion FP may be provided between the pair of terminal portions TP1 and TP2, and may connect the pair of terminal portions TP1 and TP2.

Each of photoelectric conversion regions PR may be formed in each of photodiode regions. For example, the photoelectric conversion regions PR may be formed using an ion implantation process.

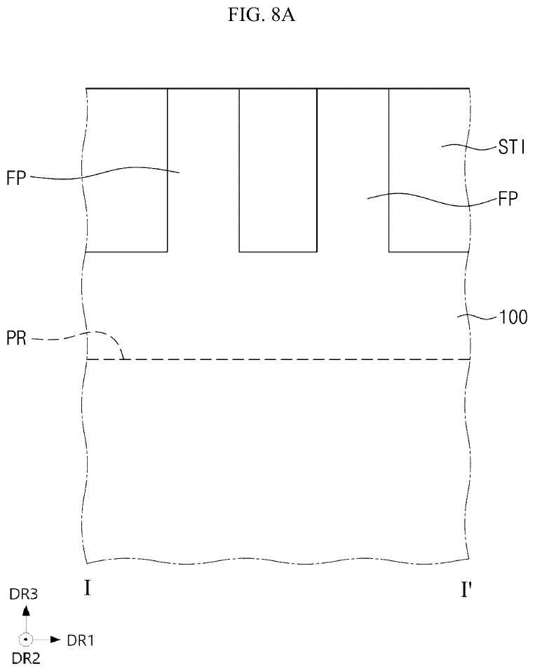

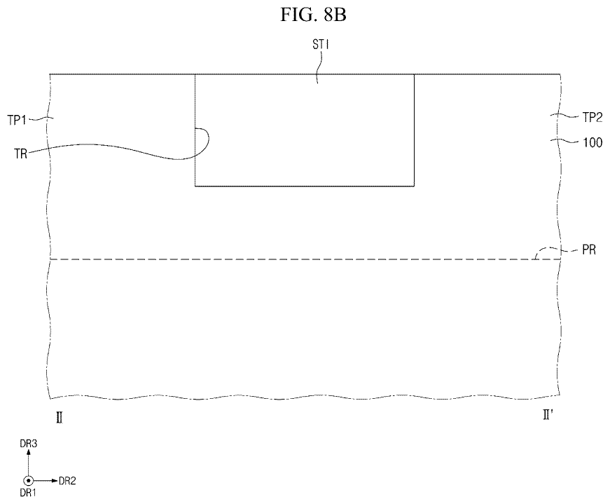

Referring to FIGS. 8A and 8B, an insulating layer (not shown) may be formed on the first surface of the substrate 100 in which the shallow trench TR is formed. The insulating layer (not shown) may include silicon oxide.

The insulating layer (not shown) may fill the shallow trench TR and cover the first surface of the substrate 100. The insulating layer (not shown) may be planarized until an upper surface of the substrate 100 is exposed. The planarization of the insulating layer may be performed using an etch-back process or a chemical mechanical polishing (CMP) process. As a result, a shallow element isolation pattern STI may be formed. An upper surface of the shallow element isolation pattern STI may be coplanar with the upper surface of the substrate 100, specifically an upper surface of the first active region ATR1.

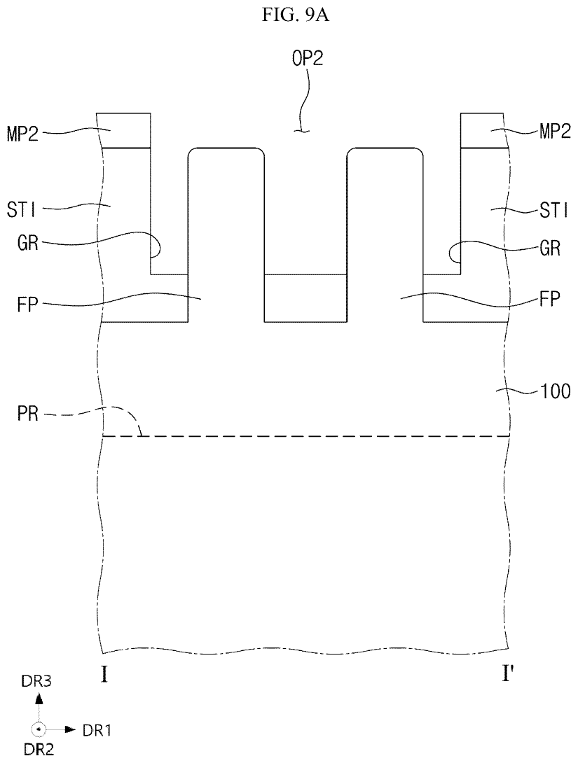

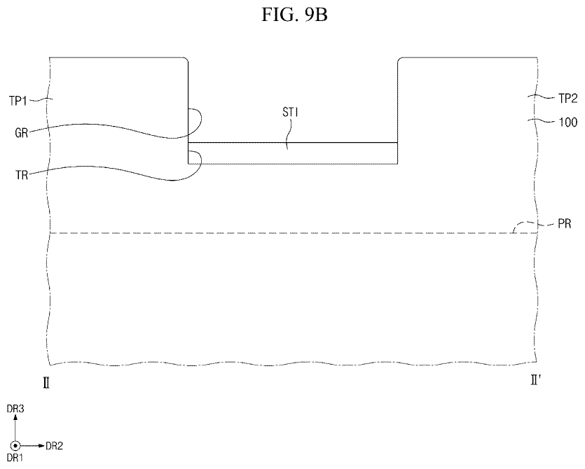

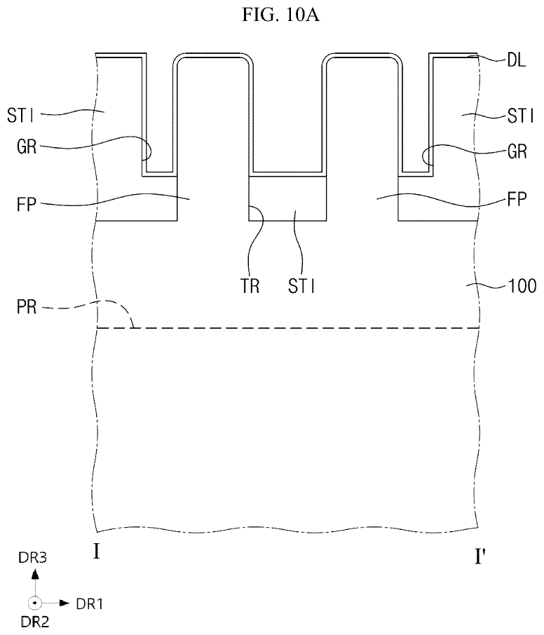

Referring to FIGS. 9A and 9B, a second mask pattern MP2 may be formed on the shallow element isolation pattern STI. The second mask pattern MP2 may have a second opening OP2 defining a gate recess GR. An etching process may be performed on the shallow element isolation pattern STI using the second mask pattern MP2 as an etch mask. The etching process may include a front-side anisotropic etching process. Etching ions used in the etching process may have etch selectivity with respect to the substrate 100. Accordingly, the shallow element isolation pattern STI exposed through the second opening OP2 may be etched, and the first active region ATR1 of the substrate 100 may remain.

When one surface of the shallow element isolation pattern STI is recessed by the etching process, the gate recess GR may be formed. The gate recess GR may expose a portion of the first active region ATR1. For example, the gate recess GR may expose a side surface of the fin portion FP. In addition, the gate recess GR may expose a side surface of the terminal portion TP. As a result, the gate recess GR may be defined by the fin portion FP, the terminal portion TP, and the shallow element isolation pattern STI.

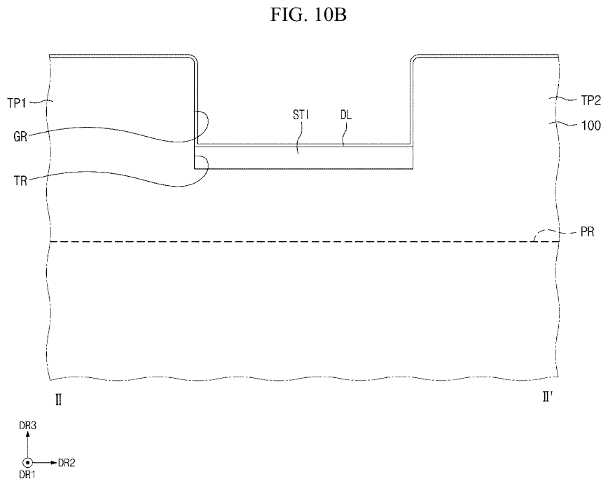

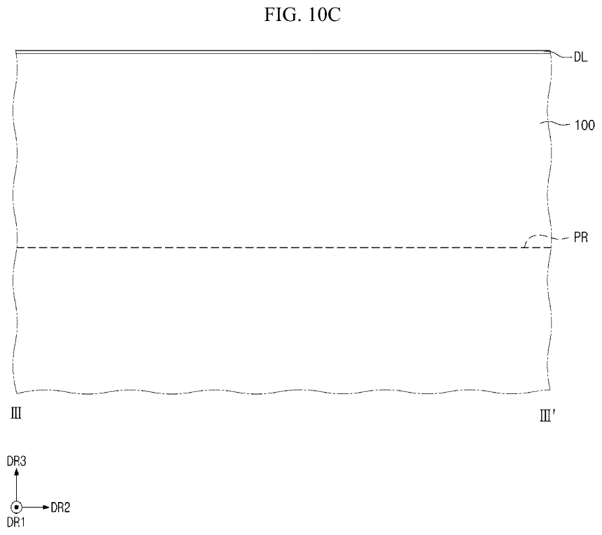

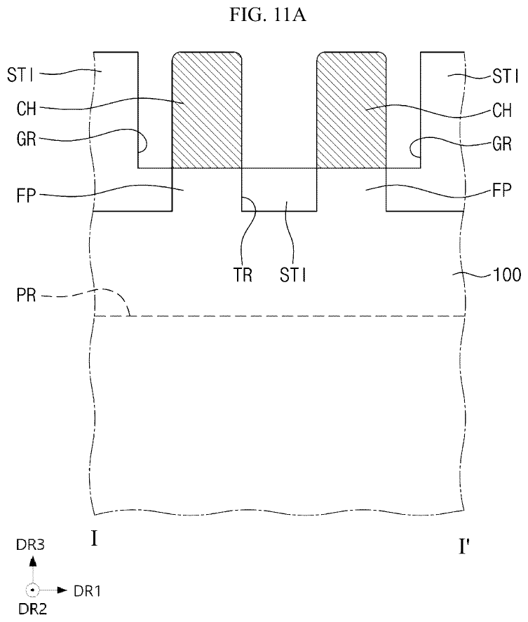

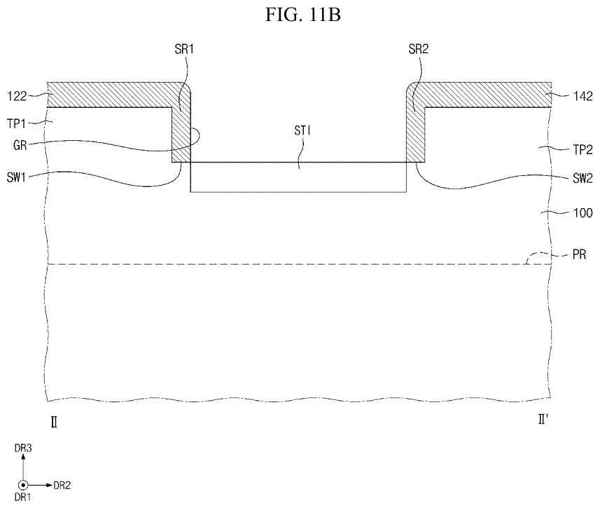

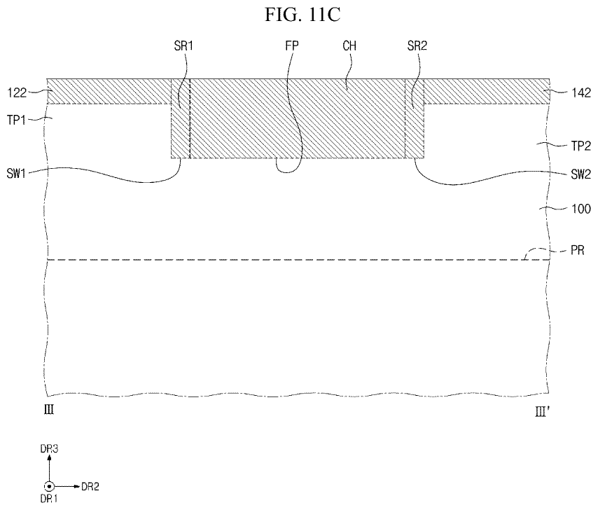

Referring to FIGS. 10A to 11C, an isotropic doping process may be performed on the first surface of the substrate 100 in which the gate recess GR is formed. The isotropic doping process may include a plasma assisted doping (PLAD) process, a spin-on dopant (SOD) process, a chemical vapor deposition (CVD) & diffusion process, and a mono-layer doping (MLD) process.

By performing the isotropic doping process, a channel region CH may be formed in the fin portion FP.

In addition, by performing the isotropic doping process, a source/drain region SD may be formed in the terminal portion TP. The source/drain region SD may be simultaneously formed with the channel region CH by performing the isotropic doping process.

In addition, a side region SR may be formed in a sidewall portion SW by performing the isotropic doping process. The side region SR may also be simultaneously formed with the source/drain region SD and the channel region CH by performing the isotropic doping process.

Since the source/drain region SD, the side region SR, and the channel region CH are formed together by the isotropic doping process, a conductivity type of the source/drain region SD, a conductivity type of the side region SR, and a conductivity type of the channel region CH may be the same.

Referring to FIGS. 10A to 10C, in one embodiment, a doping film DL may be conformally formed on the first surface of the substrate 100 in which the gate recess GR is formed. The doping film DL may include dopants. The dopants may have a second conductivity type different from a first conductivity type. For example, the doping film DL may be conformally formed on a portion of the fin portion FP that is exposed through the gate recess GR. The doping film DL may be conformally formed on a side surface and an upper surface of the exposed portion of the fin portion FP.

In addition, the doping film DL may also be formed on an inner surface of the shallow element isolation pattern STI defining the gate recess GR. In addition, the doping film DL may also be conformally formed on an upper surface and a side surface of the terminal portion TP. The side surface of the terminal portion TP may correspond to one surface of the sidewall portion.

Referring to FIGS. 11A to 11C, an annealing process may be performed to diffuse the dopants included in the doping film DL into the first active region ATR1. Further, the annealing process may also be performed to activate the diffused dopants.

For example, the channel region CH may be formed in the exposed portion of the fin portion FP by performing the annealing process. The dopants may be diffused into the exposed portion of the fin portion FP. Since the doping film DL is conformally formed on the side surface and the upper surface of the exposed portion of the fin portion FP, the diffused dopants may be uniformly distributed in the exposed portion of the fin portion FP. Therefore, the formed channel region CH may have a substantially uniform dopant concentration. For example, the dopant concentration may be substantially uniform (e.g., substantially the same) throughout the channel region CH.

Since the doping film DL is formed on the portion of the fin portion FP exposed by the gate recess GR, the channel region CH may be substantially formed in the exposed portion of the fin portion FP. The remaining portion (e.g., the non-exposed portion) of the fin portion FP positioned in the shallow element isolation pattern STI may not be substantially doped. However, depending on the process conditions of the annealing process, the channel region CH may extend toward the remaining portion of the fin portion FP.

The source/drain region SD may be formed in a portion of the terminal portion TP by performing the annealing process. For example, the dopants included in the doping film DL formed on the terminal portion TP may be diffused into the portion of the terminal portion TP by the annealing process, and the source/drain region SD may be formed in the terminal portion TP. Since the doping film DL is conformally formed on the terminal portion TP, the diffused dopants may be uniformly distributed in the portion of the terminal portion TP. Therefore, the formed source/drain region SD may have a substantially uniform dopant concentration.

In addition, by performing the annealing process, the side region SR may be formed in another portion of the terminal portion TP. Said another portion of the terminal portion TP may correspond to the sidewall portion SW. The side region SR is provided between the source/drain region SD and the channel region CH and may connect the source/drain region SD and the channel region CH.

The dopants in the doping film DL formed on the sidewall portion SW may be diffused into the sidewall portion SW by performing the annealing process, and the side region SR may be formed in the sidewall portion SW. Since the doping film DL is conformally formed on the sidewall portion SW, the diffused dopants may be uniformly distributed in the sidewall portion SW. Therefore, the formed side region SR may have a substantially uniform dopant concentration.

After the channel region CH is formed, the remaining portion of the doping film DL may be removed. Therefore, the upper surface and the side surface of the fin portion FP in which the channel region CH is formed may be exposed again. In addition, the upper surface and the side surface of the terminal portion TP may also be exposed again.

Alternatively, in one embodiment, the isotropic doping process may be performed using the PLAD process. In this case, dopants in a plasma may diffuse into the fin portion FP through the upper surface and the exposed side surfaces of the fin portion FP, and the diffused dopants may be uniformly distributed in the fin portion FP. Therefore, the channel region CH may be formed in the fin portion FP. Similarly, the source/drain region SD and the side region SR having the uniform dopant concentration may be formed together with the channel region CH using the PLAD process.

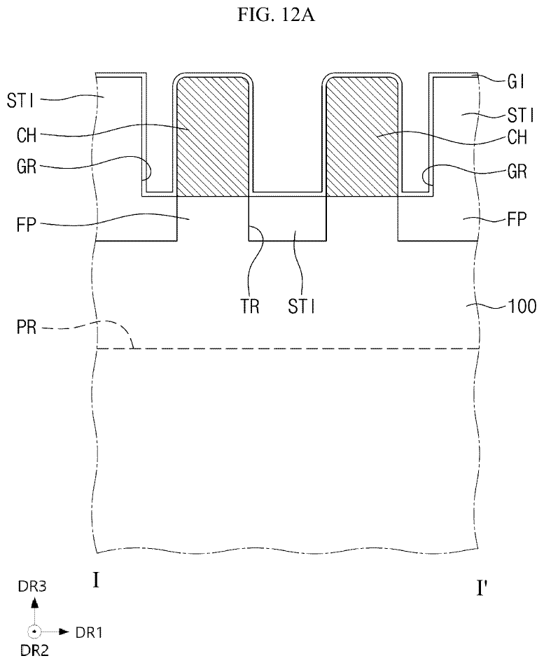

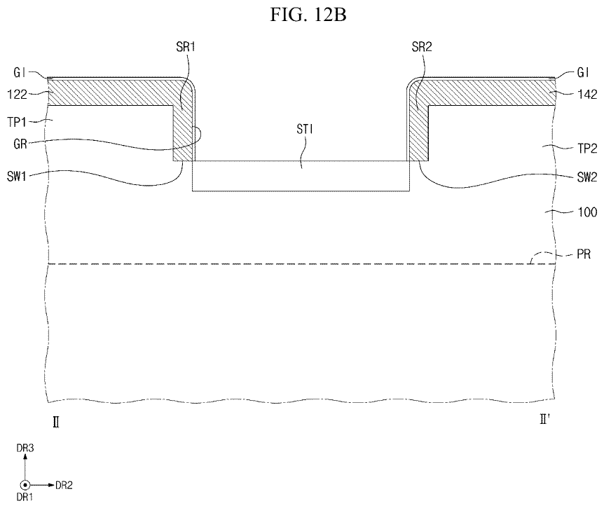

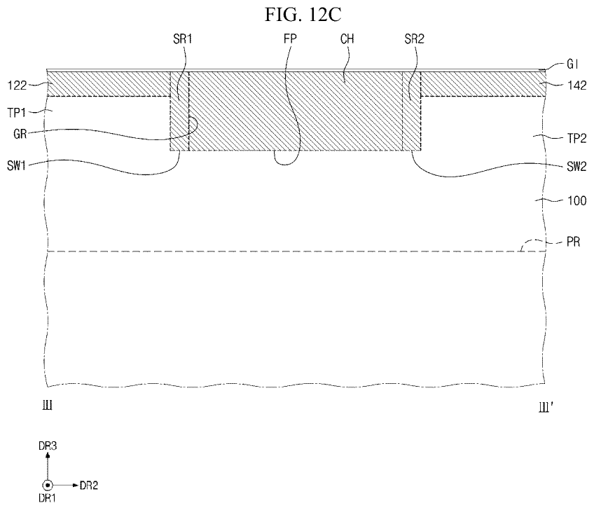

Referring to FIGS. 12A to 12C, a gate insulating layer GI may be conformally formed on the first surface of the substrate 100 in which the gate recess GR is formed. The gate insulating layer GI may include silicon oxide, silicon nitride, or silicon oxynitride.

The gate insulating layer GI may be conformally formed on the first surface of the substrate 100. For example, the gate insulating layer GI may be conformally formed on the upper surface and side surface of the exposed first active region ATR1. The gate insulating layer GI may be conformally formed on the upper surface of the fin portion FP and the side surface of the fin portion FP exposed by the gate recess GR. The gate insulating layer GI may also be conformally formed on the upper surface and the side surface of the terminal portion TP. The gate insulating layer GI may also be formed on one surface of the sidewall portion SW. The gate insulating layer GI may also be formed on the shallow element isolation pattern STI.

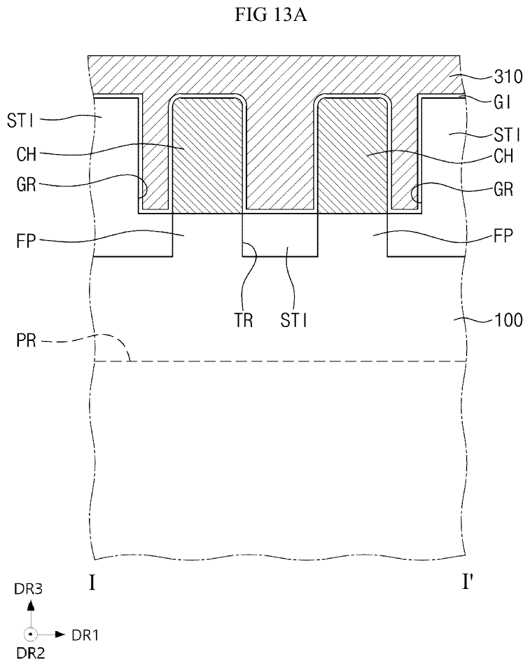

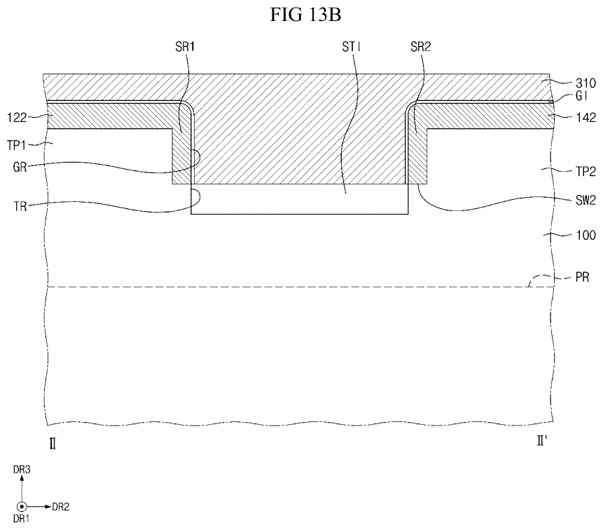

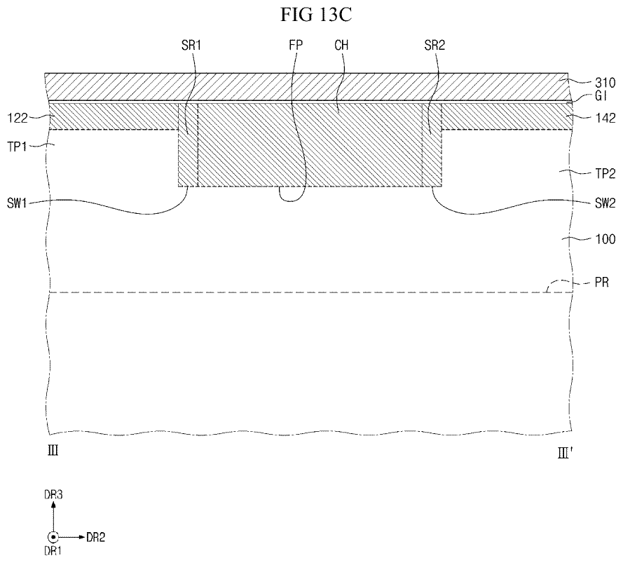

Referring to FIGS. 13A to 13C, a conductive layer 310 may be formed on the first surface of the substrate 100 on which the gate insulating layer GI is formed. The conductive layer 310 may fill the gate recess GR. The conductive layer 310 may cover the first surface of the substrate 100. The conductive layer 310 may include polysilicon or a metal. The polysilicon may be doped with dopants having the first conductivity type.

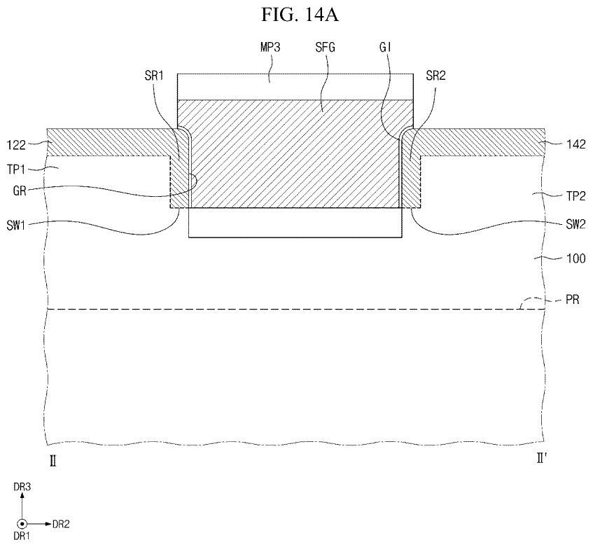

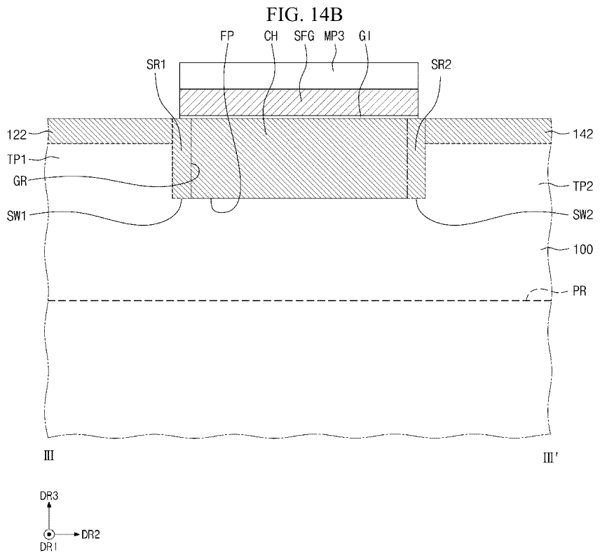

Referring to FIGS. 14A and 14B, a source follower gate SFG may be formed by etching the conductive layer 310. For example, a third mask pattern MP3 may be formed on the conductive layer 310. The third mask pattern MP3 may define the source follower gate SFG. An etching process may be performed on the conductive layer 310 using the third mask pattern MP3 as an etching mask. The etching process may include a front-side anisotropic etching process. Accordingly, a portion of the conductive layer 310 exposed by the third mask pattern MP3 may be etched, and the source follower gate SFG may be formed. After the source follower gate SFG is formed, the third mask pattern MP3 may be removed.

During the etching process, the gate insulating layer GI may also be etched. However, etching ions used in the etching process may have etch selectivity with respect to the shallow element isolation pattern STI. Accordingly, the gate insulating layer GI may be etched, but the shallow element isolation pattern STI may remain.

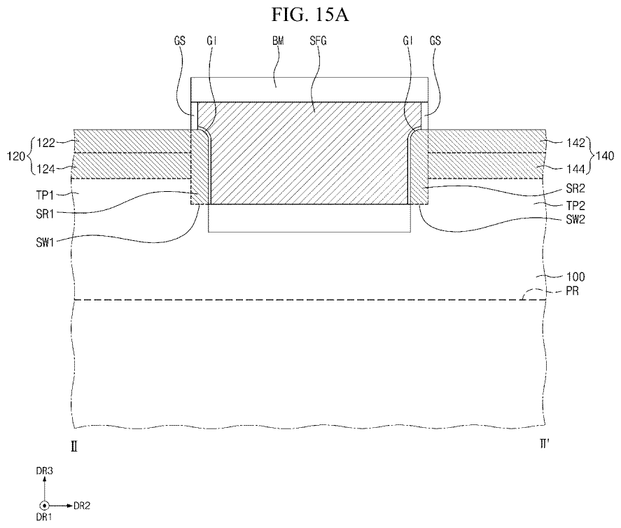

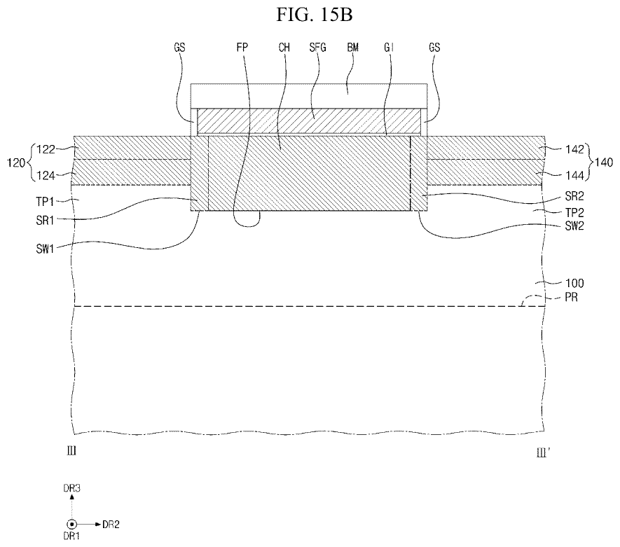

Referring to FIGS. 15A and 15B, a gate spacer GS may be formed on a side surface of the formed source follower gate SFG. The gate spacer GS may include silicon oxide, silicon nitride, or silicon oxynitride.

After the gate spacer GS is formed, a blocking mask BM may be formed. The blocking mask BM may cover the source follower gate SFG and the gate spacer GS. For example, the blocking mask BM may be provided on an upper surface of the source follower gate SFG and an upper surface of the gate spacer GS.

After the blocking mask BM is formed, the source/drain region SD may be formed. For example, a doping process may be performed on the first surface of the substrate 100 in which the source follower gate SFG is formed. The doping process may be an anisotropic doping process. For example, the doping process may include an ion implantation process.

By performing the doping process, the source/drain region SD may be formed in the terminal portion TP. The doping process may implant dopants having the second conductivity type into the terminal portion TP. In this case, the dopants may not be implanted into the source follower gate SFG due to the blocking mask BM and the gate spacer GS. For example, the blocking mask BM and the gate spacer GS may function as ion blockers. Accordingly, the source follower gate SFG formed of polysilicon doped with dopants having the first conductivity type may not be doped with dopants having the second conductivity type.

The source/drain region SD may be aligned by the gate spacer GS. For example, an edge of the source/drain region SD may be vertically aligned with an edge of the gate spacer GS. In addition, the side region SR formed under the gate spacer GS may not be doped by the doping process. In some embodiments, the doping process may include annealing. In this case, some of the implanted ions may be diffused into the side region by the annealing. In this case, the side region SR may include upper portions SR11 and SR21 that are connected to the source/drain region SD. The side region SR may further include lower portions SR12 and SR22 that are positioned under the upper portions SR11 and SR21 in the third direction DR3. Dopant concentrations of the upper portions SR11 and SR21 of the side region SR may be greater than dopant concentrations of the lower portions SR12 and SR22 of the side region SR. In some embodiments, the doping process may be omitted. In this case, the side region SR may be substantially uniformly doped with dopants having the second conductivity type.

After the source/drain region SD is formed, the blocking mask BM may be removed. Therefore, the upper surface of the source follower gate SFG and the upper surface of the gate spacer GS may be exposed.

The source/drain region SD may extend in a depth direction by the doping process. For example, the source/drain region SD may extend in the third direction DR3. As a result, the source/drain region SD formed by the isotropic doping process may be referred to as an upper region of the source/drain region SD, and the source/drain region SD may extend from the upper region to a lower region by the anisotropic doping process. The source/drain region SD formed by the anisotropic doping process may overlap the upper region.

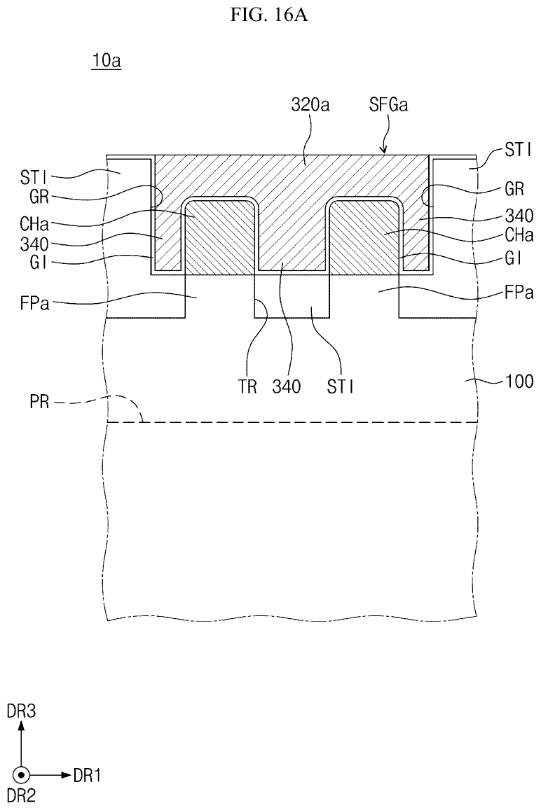

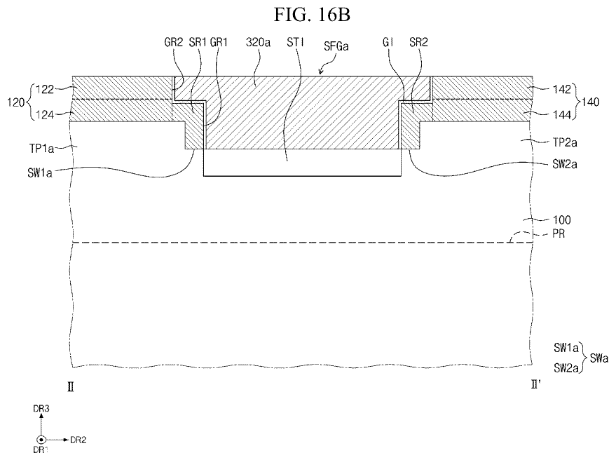

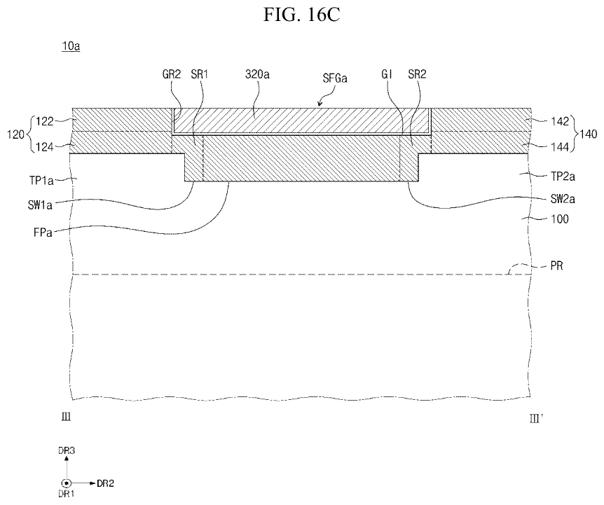

FIG. 16A is a cross-sectional view of an image sensor 10a according to one embodiment of the present disclosure, which is a cross-sectional view corresponding to line I-I′ of FIG. 5. FIG. 16B is a cross-sectional view of the image sensor 10a according to one embodiment of the present disclosure, which is a cross-sectional view corresponding to line II-II′ of FIG. 5. FIG. 16C is a cross-sectional view of the image sensor 10a according to one embodiment of the present disclosure, which is a cross-sectional view corresponding to line III-III′ of FIG. 5.

Most of the components and materials constituting the image sensor 10a described below are substantially the same as or similar to the components and materials of the image sensor 10 described above with reference to FIGS. 1 to 6C. Therefore, for convenience of explanation, differences from the above-described image sensor 10 will be mainly described.

Referring to FIGS. 16A to 16C, a fin portion FPa may be recessed. A level of an upper end of the fin portion FPa may be lower than a level of one surface of a shallow element isolation pattern STI. In addition, the level of the upper end of the fin portion FPa may be lower than a level of the first surface of a substrate 100. However, a channel region CHa may still be formed in a portion of the fin portion FPa protruding from the shallow element isolation pattern STI (e.g., an exposed portion of the fin portion FPa).

A source follower gate SFGa may include vertical portions 340 and a horizontal portion 320a and may be provided in the shallow element isolation pattern STI. For example, the source follower gate SFGa may be buried in the shallow element isolation pattern STI.

Accordingly, the parasitic capacitance generated between the source follower gate SFGa and an adjacent other gate may be reduced.

In addition, the parasitic capacitance generated between the source follower gate SFGa and adjacent contact patterns may be reduced.

For example, a level, in the third direction DR3, of an upper end of the source follower gate SFGa may be substantially the same as the level of one surface of the shallow element isolation pattern STI. In addition, the level of the upper end of the source follower gate SFGa may be substantially the same as the level of the first surface of the substrate 100.

A level of an upper surface of the horizontal portion 320a may be substantially coplanar with the surface of the shallow element isolation pattern STI. In addition, the level of the upper surface of the horizontal portion 320a may be substantially coplanar with the first surface of the substrate 100. In addition, the level of the upper surface of the horizontal portion 320a may be substantially coplanar with one surface of a terminal portion TPa.

A gate insulating layer GI may be interposed between the horizontal portion 320a and the terminal portion TPa. The gate insulating layer GI may also be interposed between the horizontal portion 320a and a sidewall portion SWa. The gate insulating layer GI may also be interposed between the horizontal portion 320a and a side region SR.

Since the horizontal portion 320a of the source follower gate SFGa is provided in the shallow element isolation pattern STI, a gate spacer GS may be omitted. In this case, the sidewall portion SWa in which the side region SR is formed may be provided under the horizontal portion 320a. An edge of the source/drain region SD and an edge of the horizontal portion 320a may be vertically aligned. For example, an edge of the source/drain region SD may be substantially coplanar with an edge of the horizontal portion 320a in the third direction DR3.

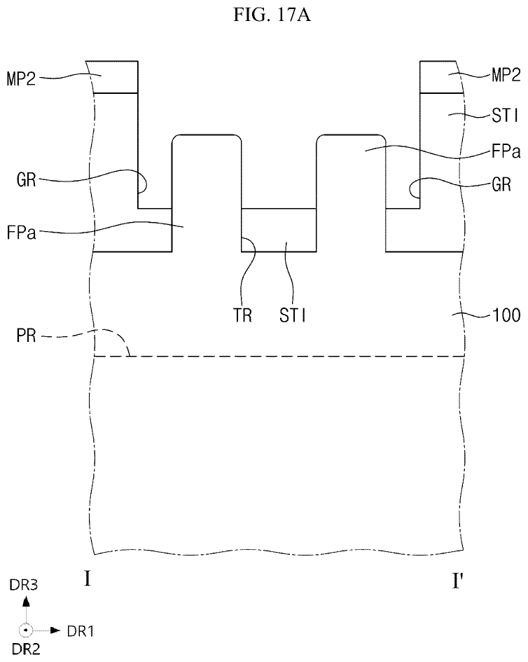

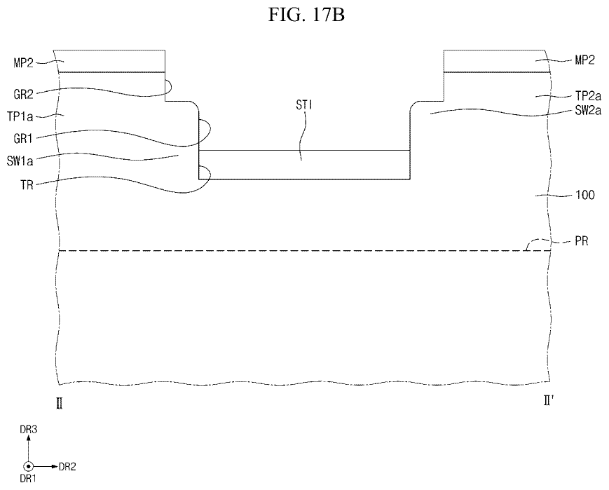

FIGS. 17A to 19A are cross-sectional views for showing a method of manufacturing an image sensor 10a according to one embodiment of the present disclosure. FIGS. 17B to 19B are cross-sectional views for showing the method of manufacturing the image sensor 10a according to one embodiment of the present disclosure.

Referring to FIGS. 17A and 17B, in one embodiment, a portion of the fin portion FPa may be etched together during the process of forming a gate recess GR. Etching ions used in the etching process may have etch selectivity with respect to the fin portion Fpa. For example, an etch rate of the shallow element isolation pattern STI by the etching ions may be greater than an etch rate of the fin portion Fpa by the etching ions. For example, the etch rate of the shallow element isolation pattern STI by the etching ions may be about five times or more greater than the etch rate of the fin portion Fpa by the etching ions.

Accordingly, the level of the upper end of the fin portion Fpa may be lowered during the process of forming the gate recess GR.

However, in order to prevent the entire terminal portion Tpa from being etched during the process of forming the gate recess GR, the second mask pattern MP2 may also be formed on the terminal portion Tpa. However, the second mask pattern MP2 may be formed on a portion of the terminal portion Tpa in which the source/drain region SD is to be formed, and the remaining portion of the terminal portion Tpa may be exposed. The remaining portion of the terminal portion Tpa may correspond to the sidewall portion Swa. Accordingly, a first gate recess GR1 may be formed when the shallow element isolation pattern STI is etched, and a second gate recess GR2 may be formed when the remaining portion of the terminal portion Tpa is etched.

A level of a bottom surface of the second gate recess GR2 may be substantially the same as the level of the upper end of the fin portion Fpa. A level of an upper end of the sidewall portion Swa may be substantially the same as the level of the upper end of the fin portion Fpa.

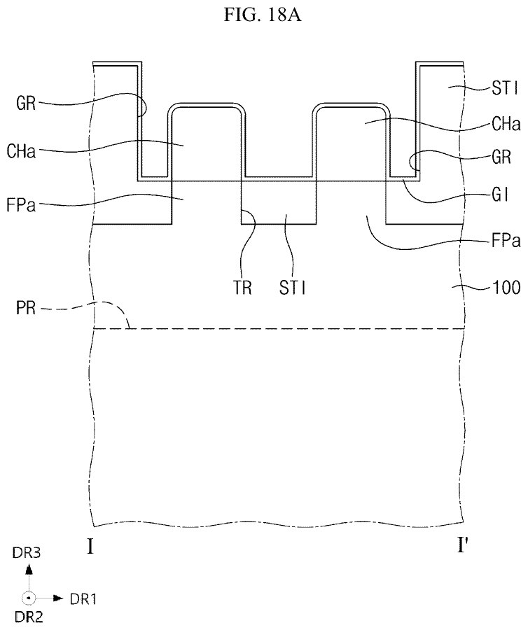

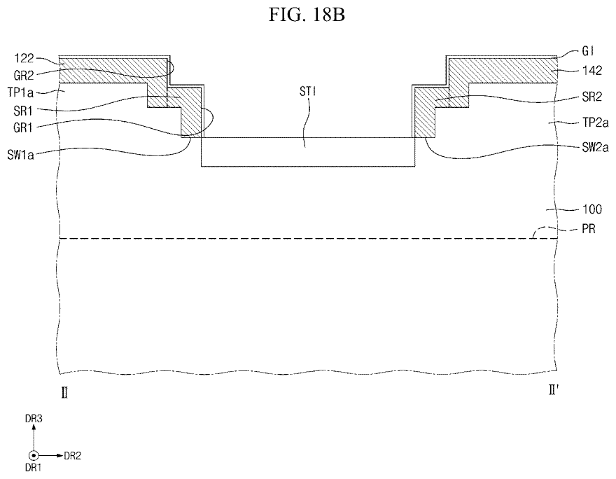

Referring to FIGS. 18A and 18B, the gate insulating layer GI may be conformally formed on the first surface of the substrate 100 in which the first and second gate recesses GR1 and GR2 are formed. The gate insulating layer GI may be conformally formed on an upper surface and an exposed side surface of the fin portion Fpa. In addition, the gate insulating layer GI may be conformally formed on an upper surface and a side surface of the terminal portion Tpa.

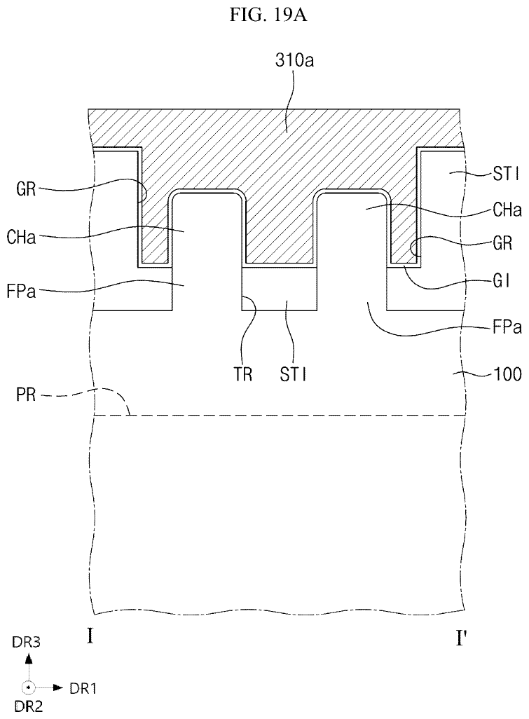

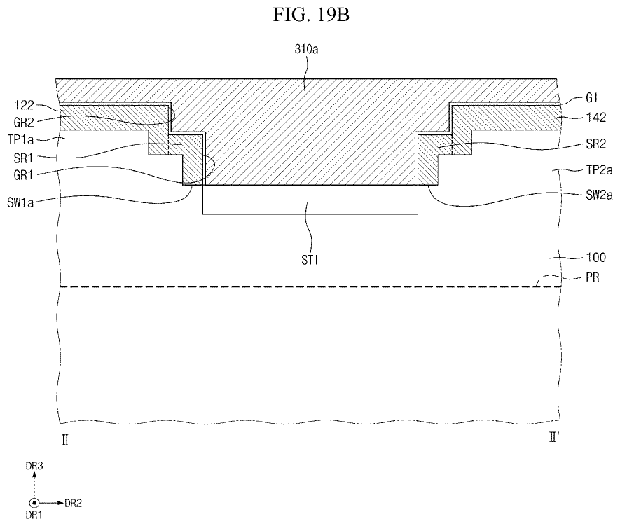

Referring to FIGS. 19A and 19B, a conductive layer 310a may be formed on the first surface of the substrate 100 on which the gate insulating layer GI is formed. The conductive layer 310a may fill the first and second gate recesses GR1 and GR2. The conductive layer 310a may cover the first surface of the substrate 100. The conductive layer 310a may include polysilicon or a metal. The polysilicon may be doped with dopants having the first conductivity type.

Thereafter, the conductive layer 310a may be patterned to form the source follower gate SFGa.

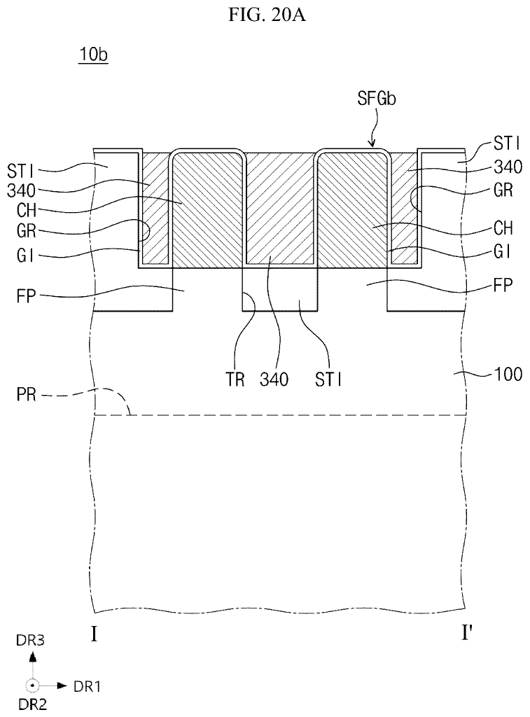

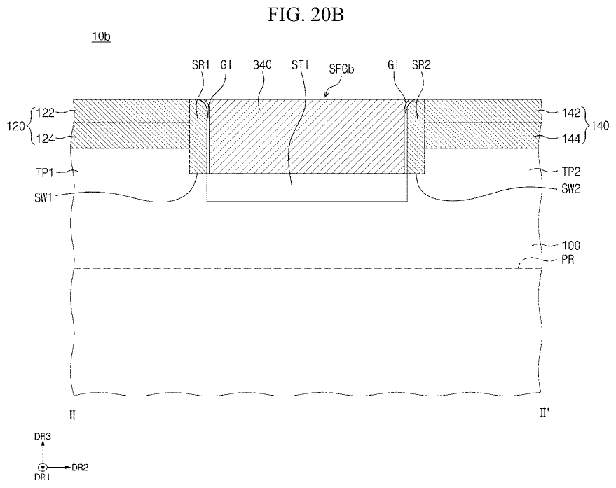

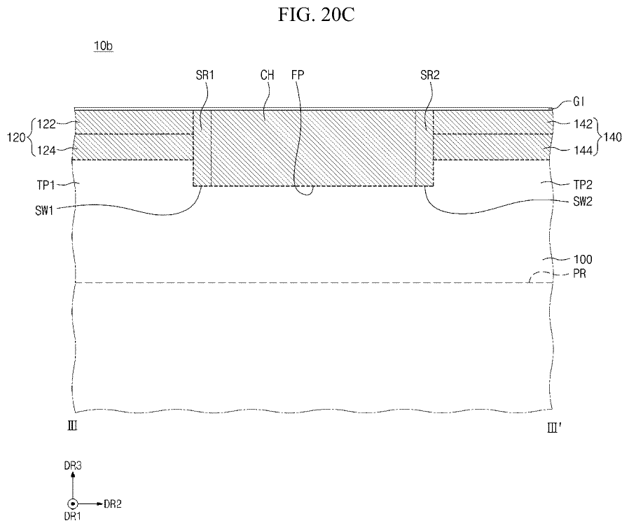

FIG. 20A is a cross-sectional view of an image sensor 10b according to one embodiment of the present disclosure, which is a cross-sectional view corresponding to line I-I′ of FIG. 5. FIG. 20B is a cross-sectional view of the image sensor 10b according to one embodiment of the present disclosure, which is a cross-sectional view corresponding to line II-II′ of FIG. 5. FIG. 20C is a cross-sectional view of the image sensor 10b according to one embodiment of the present disclosure, which is a cross-sectional view corresponding to line III-III′ of FIG. 5.

Most of the components and materials constituting the image sensor 10b described below are substantially the same as or similar to the components and materials of the image sensor 10 described above with reference to FIGS. 1 to 6C. Therefore, for convenience of explanation, differences from the above-described image sensor 10 will be mainly described.

Referring to FIGS. 20A to 20C, a source follower gate SFGb may omit the horizontal portion 320. In this case, the vertical portions 340 may be spaced apart from each other. The fin portion FP may be provided between the vertical portions 340 to disconnect the vertical portions 340 from each other. Each of contact patterns (not shown) may be connected to each of the vertical portions 340 and may be electrically connected to each other. Accordingly, electrical signals may be applied simultaneously to the vertical portions 340.

A level of an upper end of the vertical portion 340 may be substantially the same as a level of an upper end of the shallow element isolation pattern STI. The level, in the third direction DR3, of the upper end of the vertical portion 340 may also be substantially the same as a level of an upper end of the fin portion FP. The level of the upper end of the vertical portion 340 may also be substantially the same as a level of the first surface of the substrate 100.

Therefore, the parasitic capacitance generated between the source follower gate SFGb and an adjacent other gate may be reduced.

In addition, the parasitic capacitance generated between the source follower gate SFGb and adjacent contact patterns may also be reduced.

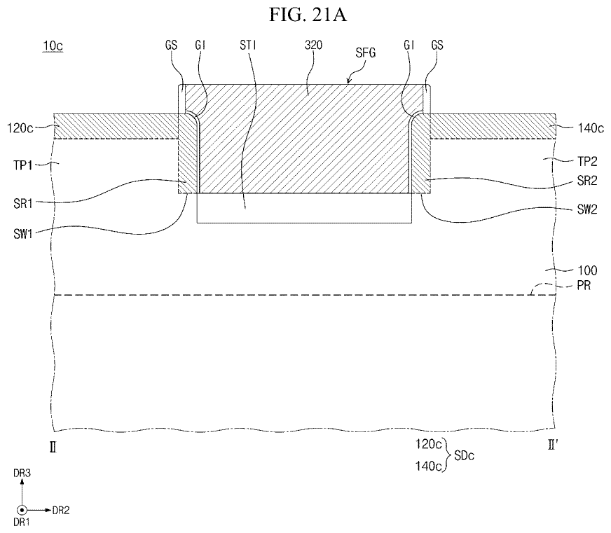

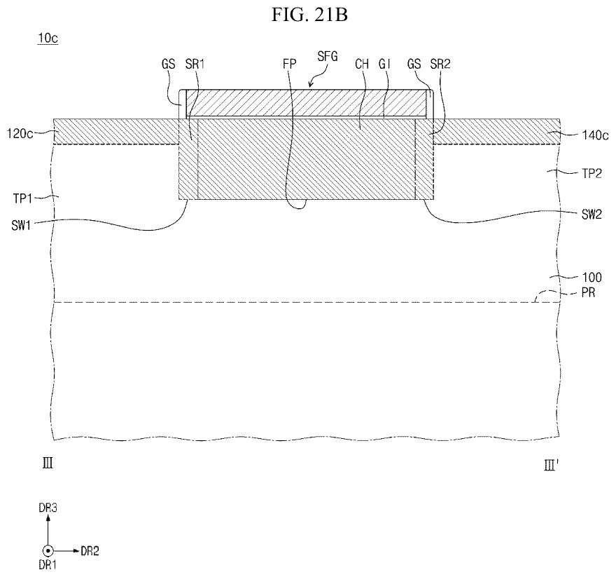

FIG. 21A is a cross-sectional view of an image sensor 10c according to one embodiment of the present disclosure, which is a cross-sectional view corresponding to line II-II′ of FIG. 5. FIG. 21B is a cross-sectional view of the image sensor 10c according to one embodiment of the present disclosure, which is a cross-sectional view corresponding to line III-III′ of FIG. 5.

Most of the components and materials constituting the image sensor 10c described below are substantially the same as or similar to the components and materials of the image sensor 10 described above with reference to FIGS. 1 to 6C. Therefore, for convenience of explanation, differences from the above-described image sensor 10 will be mainly described.

Referring to FIGS. 21A and 21B, a source/drain region SDc may be formed by an isotropic doping process. For example, the source/drain region SDc may be doped together with the channel region CH through an isotropic doping process. In this case, the source/drain region SDc and the channel region CH may be doped with high-concentration dopants. Therefore, a dopant concentration of the source/drain region SDc may be substantially the same as a dopant concentration of the channel region CH.

The side region SR may also be doped together with the channel region CH and the source/drain region SDc through the isotropic doping process.

Accordingly, a method of manufacturing an image sensor with a simplified manufacturing process and reduced manufacturing cost can be provided.

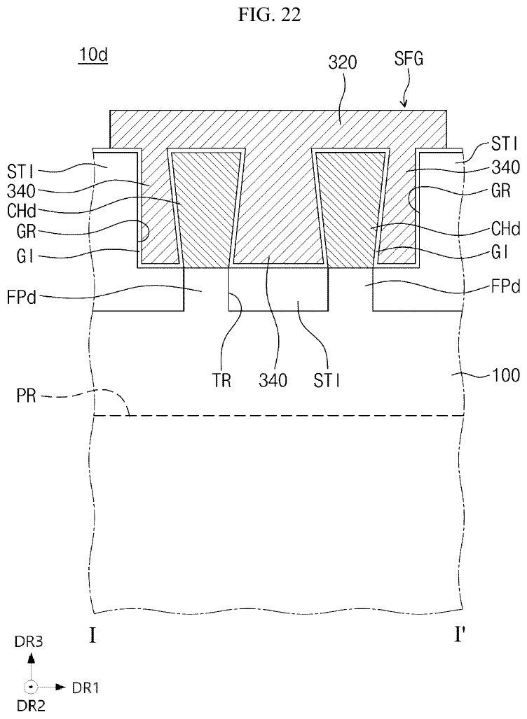

FIG. 22 is a cross-sectional view of an image sensor 10d according to one embodiment of the present disclosure, which is a cross-sectional view corresponding to line I-I′ of FIG. 5.

Most of the components and materials constituting the image sensor 10d described below are substantially the same as or similar to the components and materials of the image sensor 10 described above with reference to FIGS. 1 to 6C. Therefore, for convenience of explanation, differences from the above-described image sensor 10 will be mainly described.

Referring to FIG. 22, a fin portion FPd may have a cross-sectional shape of a reverse trapezoid. For example, the fin portion FPd may have a width defined in a width direction of a channel, and the width of the fin portion FPd may increase toward an upper side thereof. The width of the fin portion FPd may decrease toward a lower side thereof. The width of the fin portion FPd may increase toward the first surface of the substrate 100 and may decrease as the width of the fin portion FPd is away from (e.g., along the third direction DR3) the first surface of the substrate 100 toward a second surface of the substrate 100.

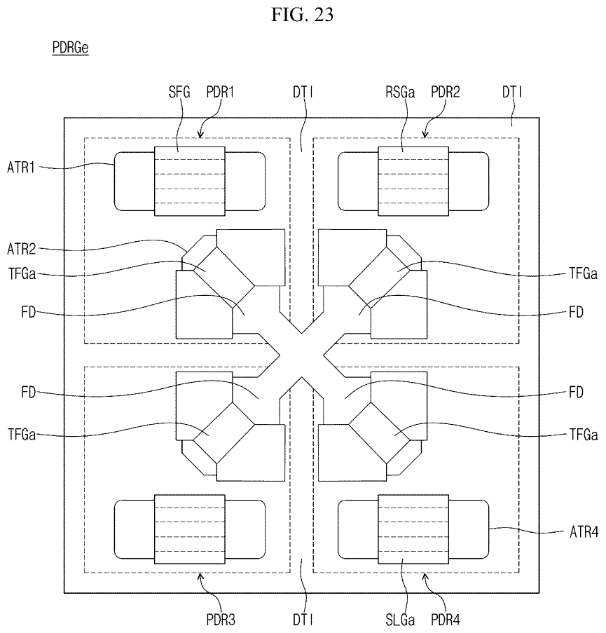

FIG. 23 is an enlarged plan view of one photodiode region group PDRGe of an image sensor 10e according to one embodiment of the present disclosure.

Referring to FIG. 23, the structure of the fin-type field-effect transistor (Fin-FET) applied to the source follower transistor according to some embodiments of the present disclosure may also be applied to a transfer transistor, a reset transistor, or a selection transistor. For example, the structure of the Fin-FET according to some embodiments of the present disclosure may be applied to at least one of the source follower transistor, the transfer transistor, the reset transistor, or the selection transistor.

Accordingly, a transfer transistor, a reset transistor, or a selection transistor having a junctionless transistor structure may be provided.

According to embodiments of the present disclosure, a channel region having a substantially uniform dopant concentration can be formed in a fin portion by an isotropic doping process. Therefore, an area of the channel region can be increased, and a width of a channel can be substantially increased. Accordingly, electrical characteristics of a transistor can be improved, and an image sensor with enhanced performance can be provided.

In addition, according to embodiments of the present disclosure, since the channel region in the fin portion is doped with dopants having the same conductivity type as that of a source/drain region, a junctionless transistor can be provided. Therefore, traps between the fin portion and a gate dielectric layer can be avoided, so that electrical characteristics of the transistor can be improved. For example, trans-conductance of the transistor can be enhanced.

In addition, according to embodiments of the present disclosure, due to a side region positioned between the source/drain region and the channel region and doped with dopants having the same conductivity type as that of the source/drain region and the channel region, an image sensor with reduced parasitic resistance of the transistor can be provided. Accordingly, an image sensor with enhanced performance can be provided.

In addition, according to embodiments of the present disclosure, due to the side region doped by the isotropic doping process, a dopant concentration in the side region can be substantially uniformly formed. Accordingly, an area of the side region can be increased.

In addition, according to embodiments of the present disclosure, due to gates buried in a shallow element isolation pattern, parasitic capacitance generated between the gates and contacts or between the gates can be reduced. Accordingly, an image sensor with enhanced performance can be provided.

In addition, according to embodiments of the present disclosure, since the channel region and the source/drain region are formed together by the isotropic doping process, a method of manufacturing an image sensor with a simplified manufacturing process and reduced manufacturing cost can be provided.

In addition, according to embodiments of the present disclosure, since the channel region and the source/drain region are formed together by the isotropic doping process, a method of manufacturing an image sensor with a simplified manufacturing process and reduced manufacturing cost can be provided.

The above-described contents are specific embodiments for implementing the present disclosure. In addition to the above-described embodiments, the present disclosure will also include embodiments that can be simply designed around or easily changed. In addition, the present disclosure will also include technologies that can be implemented by being easily modified using the embodiments. Therefore, the scope of the present disclosure should not be limited to the above-described embodiments, but should be determined not only by the appended claims but also by the equivalents of the claims of the present disclosure.

What is claimed is:

1. An image sensor comprising:
a deep PD isolation pattern provided in a substrate doped with dopants having a first conductivity type to define photodiode region groups, each of the photodiode region groups including at least one photodiode region;
a shallow element isolation pattern filling a shallow trench recessed from a first surface of the substrate to define at least one active region in each of the photodiode region groups, the active region including a terminal portion and a fin portion;
a gate filling a gate recess formed in the shallow element isolation pattern, the gate recess exposing a portion of the fin portion; and
a gate insulating layer between the gate and the exposed portion of the fin portion,
wherein
the fin portion includes a channel region formed in the exposed portion of the fin portion and doped with dopants having a second conductivity type different from the first conductivity type,
the terminal portion includes a side region defining the gate recess and doped with dopants having the second conductivity type, and
the side region vertically overlaps the gate.

2. The image sensor of claim 1, wherein
the channel region is uniformly doped with dopants having the second conductivity type in the vertical direction.

3. The image sensor of claim 2, wherein
the side region is uniformly doped with dopants having the second conductivity type.

4. The image sensor of claim 3, wherein
a dopant concentration of the side region is the same as a dopant concentration of the channel region.

5. The image sensor of claim 1, wherein
the side region extends in a direction intersecting a longitudinal direction of the channel region.

6. The image sensor of claim 1, wherein
the terminal portion further includes a source/drain region connected to the side region and doped with dopants having the second conductivity type,
the source/drain region does not vertically overlap the gate, and
the source/drain region, the side region, the channel region, and the gate form a junctionless transistor.

7. The image sensor of claim 6, wherein
a dopant concentration of the source/drain region is greater than a dopant concentration of the side region.

8. The image sensor of claim 6, wherein
the side region is positioned between the source/drain region and the channel region, and
the side region connects the source/drain region and the channel region.

9. The image sensor of claim 7, wherein
the side region includes:
an upper portion connected to the source/drain region; and
a lower portion positioned under the upper portion, and
a dopant concentration of the upper portion is greater than a dopant concentration of the lower portion.

10. The image sensor of claim 1, wherein
the gate is doped with dopants having the first conductivity type.

11. An image sensor comprising:
a deep PD isolation pattern provided in a substrate doped with dopants having a first conductivity type to define photodiode region groups, each of the photodiode region groups including at least one photodiode region;
a shallow element isolation pattern filling a shallow trench recessed from a first surface of the substrate to define at least one active region in each of the photodiode region groups, the active region including a terminal portion and a fin portion;
a gate filling a gate recess formed in the shallow element isolation pattern to expose a portion of the fin portion, the gate including a plurality of vertical portions spaced apart from each other in the gate recess; and
a gate insulating layer between the gate and the exposed portion of the fin portion,
wherein
the fin portion includes a channel region formed in the exposed portion of the fin portion and doped with dopants having a second conductivity type different from the first conductivity type,
the terminal portion includes:
a source/drain region doped with dopants having the second conductivity type; and
a side region provided between the fin portion and the source/drain region and doped with dopants having the second conductivity type, and
a dopant concentration of the side region is less than a dopant concentration of the source/drain region.

12. The image sensor of claim 11, wherein
a level of an upper end of the fin portion is disposed at the same as a level of the first surface of the substrate, and
the fin portion disconnects the vertical portions from each other.

13. The image sensor of claim 11, wherein
a level of an upper surface of the fin portion is lower than a level of the first surface of the substrate,
the gate includes a horizontal portion connected to the vertical portions, and
a level of an upper surface of the horizontal portion is the same as a level of the first surface of the substrate.

14. The image sensor of claim 11, wherein
a width of the fin portion defined in a width direction of the channel region increases toward the first surface of the substrate.

15. A method of manufacturing an image sensor, the method comprising:
patterning a first surface of a substrate to form a shallow trench defining an active region, the active region including a terminal portion and a fin portion;
forming a shallow element isolation pattern filling the shallow trench;
patterning the shallow element isolation pattern to form a gate recess exposing side surfaces of the fin portion;
performing an isotropic doping process to form a channel region in the fin portion through an upper surface and the side surfaces of the fin portion;
forming a gate insulating layer on the fin portion; and
forming a gate filling the gate recess.

16. The method of claim 15, wherein
the performing of the isotropic doping process includes:
conformally forming a doping film including dopants on the upper surface and the exposed side surfaces of the fin portion; and
performing an annealing process to diffuse the dopants of the doping film into the fin portion.

17. The method of claim 15, wherein
the performing of the isotropic doping process includes uniformly doping dopants in a plasma on the upper surface and the exposed side surfaces of the fin portion.

18. The method of claim 15, further comprising
forming a source/drain region in the terminal portion,
wherein
the source/drain region is doped with dopants having the same conductivity type as that of the channel region.

19. The method of claim 18, wherein
the source/drain region is simultaneously formed with the channel region by the performing of the isotropic doping process.

20. The method of claim 18, wherein
the terminal portion includes a sidewall portion defining the gate recess and connected to the fin portion,
a side region is formed in the sidewall portion by the performing of the isotropic doping process,
the side region is doped with dopants having the same conductivity type as that of the channel region, and
the source/drain region, the side region, the channel region, and the gate form a junctionless transistor.
